(19) United States
(12) Patent Application Publication
(10) Pub. No.: US 2007/0009809 A1
(43) Pub. Date: Jan. 11, 2007

(54) Synthetic Nanoparticle Soil Materials

(76) Inventors: Mark P.S. Krekeler, Centreville, VA (US); Cynthia M. Tselepis, Arlington, VA (US)

Correspondence Address: GEORGE MASON UNIVERSITY;OFFICE OF TECHNOLOGY TRANSFER, MSN 5G5, 4400 UNIVERSITY DRIVE, FAIRFAX, VA, 22030, US

(21) Appl. No.: 11/456,232

(22) Filed: Jul. 10, 2006

Related U.S. Application Data
(60) Provisional application No. 60/697,379, filed on Jul. 8, 2005.

(51) Int. Cl. G03F 1/00

(52) U.S. Cl. 430/5

(57) ABSTRACT

The present invention relates to synthetic nanoparticle soil materials that comprises about 0.5% to about 20% metal powder by mass, and about 0.5% to about 30% mineral powder by mass, mixed together with quartz-rich sand and a polymorph mineral of aluminum silicate, creating a sand mixture that may be mixed with a silicic acid solution. The ratio of quartz-rich sand to the polymorph mineral of aluminum silicate is between 1:99 and 99:1. The polymorph mineral of aluminum silicate can be kyanite, andalusite, sillimanite, mullite or any variant or substitute of these minerals. The silicic acid solution can be made by mixing silicic acid powder to water in a ratio being 1:99 to 99:1. The ratio of sand mixture to silicic acid solution can be between 1:99 to 99:1.

### CROSS REFERENCE TO RELATED APPLICATIONS

The present application claims the benefit of provisional patent application Ser. No. 60/697,379 to Krekeler et al., filed on Jul. 8, 2005, entitled “Synthetic Soil Material System for Improved Created Wetland Performance,” which is hereby incorporated by reference.

### BRIEF DESCRIPTION OF THE DRAWINGS

FIG. 1 shows examples of TEM images of platy particles.

FIG. 2 shows multiple TEM images.

FIG. 3 shows TEM images of spherical particles from Tahquanemon Bay.

FIG. 4 shows an embodiment of a flow diagram for creating a synthetic nanoparticle soil material.

FIG. 5 shows another embodiment of a flow diagram for creating a synthetic nanoparticle soil material.

FIG. 6 shows an embodiment of a block diagram of a synthetic nanoparticle soil material system.

FIG. 7 shows another embodiment of a block diagram of a synthetic nanoparticle soil material system.

FIG. 8 shows an SEM image of synthetic soil with a high proportion of kyanite.

FIG. 9 shows an SEM image of synthetic soil with a high proportion of kyanite having lesser amounts of Fe-oxide material.

FIG. 10 shows an SEM image of synthetic soil with a high proportion of kyanite having lesser amounts of Fe-oxide material and showing isolated grains.

FIG. 11 shows another SEM image of the synthetic soil with a high proportion of kyanite.

FIG. 12 shows another SEM image of the synthetic soil with a high proportion of kyanite with lesser amounts of Fe-oxide material.

FIG. 13 shows another SEM image of the synthetic soil with a high proportion of kyanite.

FIG. 14 shows a exemplified graph revealing grain size analysis for a fine grain sample.

FIG. 15 shows a exemplified graph revealing grain size analysis for a coarse material.

FIG. 16 shows a exemplified graph revealing the percent of kyanite plotted against average k values.

FIG. 17 shows a graph revealing the weight percentage of the Si, Fe, and O after the 2^{nd} saturation for platy particles.

FIG. 18 shows a graph revealing the weight percentage of Si, Fe, and O after the 2^{nd} saturation for acicular particles.

FIG. 19 shows grain size distributions for a control and the 4^{th} saturation.

FIG. 20 shows an image having Si concentration in an Fe particle.

FIG. 21 shows aggregates of poorly crystalline Fe oxide/oxyhydroxide particles along with goethite crystals.

FIG. 22 shows an example of a platy crystalline Fe particle.

FIG. 23 shows a histogram of the weight percent of P₂O₅.

FIG. 24 shows a histogram of the weight percent of Al₂O₃.

FIG. 25 shows a histogram of the weight percent of Fe₂O₃.

FIG. 26 shows an X-Y plot of EDS data between Al₂O₃ and P₂O₅.

FIG. 27 shows an X-Y plot of EDS data between Fe₂O₃ and P₂O₅.

FIG. 28 shows a summation of X-ray diffraction patterns on synthetic nanoparticle soil materials.

FIG. 29 shows diffraction data in tabular format for a synthetic nanoparticle soil material as one embodiment of the present invention.

FIG. 30 shows an X-ray diffraction pattern using diffraction data from FIG. 29.

FIG. 31 shows diffraction data in tabular format for a synthetic nanoparticle soil material another one embodiment of the present invention.

FIG. 32 shows an X-ray diffraction pattern using diffraction data from FIG. 31.

FIG. 33 shows diffraction data in tabular format for a synthetic nanoparticle soil material another one embodiment of the present invention.

FIG. 34 shows an X-ray diffraction pattern using diffraction data from FIG. 33.

FIG. 35 shows diffraction data in tabular format for a synthetic nanoparticle soil material another one embodiment of the present invention.

FIG. 36 shows an X-ray diffraction pattern using diffraction data from FIG. 35.

FIG. 37 shows diffraction data in tabular format for a synthetic nanoparticle soil material another one embodiment of the present invention.

FIG. 38 shows an X-ray diffraction pattern using diffraction data from FIG. 37.

FIG. 39 shows diffraction data in tabular format for a synthetic nanoparticle soil material another one embodiment of the present invention.

FIG. 40 shows an X-ray diffraction pattern using diffraction data from FIG. 39.

FIG. 41 shows diffraction data in tabular format for a synthetic nanoparticle soil material another one embodiment of the present invention.

FIG. 42 shows an X-ray diffraction pattern using diffraction data from FIG. 41.

FIG. 43 shows diffraction data in tabular format for a synthetic nanoparticle soil material another one embodiment of the present invention.

FIG. 44 shows an X-ray diffraction pattern using diffraction data from FIG. 43.

FIG. 45 shows diffraction data in tabular format for a synthetic nanoparticle soil material another one embodiment of the present invention.

FIG. 46 shows an X-ray diffraction pattern using diffraction data from FIG. 45.

FIG. 47 shows an example of a simple diagram illustrating a proposed stratigraphy of a catchment basin using synthetic soil.

FIG. 48 shows example of a simple diagram illustrating a proposed stratigraphy of a created wetland using synthetic soil.

FIG. 49 shows an example of a simple diagram illustrating synthetic soil bagged in semi-permeable material and being used as a lining in a drainage system.

### DETAILED DESCRIPTION OF THE INVENTION

The present invention embodies a synthetic nanoparticle soil material (also referred to herein as “synthetic soil”) and its production.

I. Introduction

Wetlands play an intricate role in maintaining the Earth's natural habitats. Wetland ecosystems are essential environments for a variety of species, such as fish, birds, plants, insects, amphibians, reptiles and mammals. They preserve and provide food for all life at microscopic and macroscopic scales, as well as contribute to the maintenance of water filtration. Water filtration is extremely important in trapping pollutants and for purification purposes.

Wetland production and conservation is necessary to keep these ecosystems thriving. Knowing the chemical makeup and the mineralogy of these systems are essential in understanding the underlying relationships that maintain these intricate systems. This knowledge should be maintained and taught to stop the increasing degradation of wetlands.

Over the past one-hundred years, the decline of wetlands has been dramatic. This decline is expected to continue. Due to agriculture development and an increasing population growth, the United States Geological Survey (USGS) has estimated that over 36 million acres has been lost in the Midwest, such as in the states of Illinois, Indiana, Iowa, Michigan, Minnesota, Ohio and Wisconsin. Except for maybe Alaska and Hawaii, every state has probably lost over 53% of their original wetlands in the past 200 years. Therefore, it is necessary to explore new technologies that help maintain build or rebuild working wetland systems.

II. Preliminary Investigation

To develop the synthetic nanoparticle soil material technology, data from transmission electron microscopy (TEM) from natural ortsteins and hydromorphic soils may be used. These soils may be associated with any wetland, such as those from the Lake Superior region. It should be noted that detailed studies of the particle morphology, chemistry and crystallinity of the clay fraction of ortsteins and hydromorphic soils were not a major consideration of this investigation.

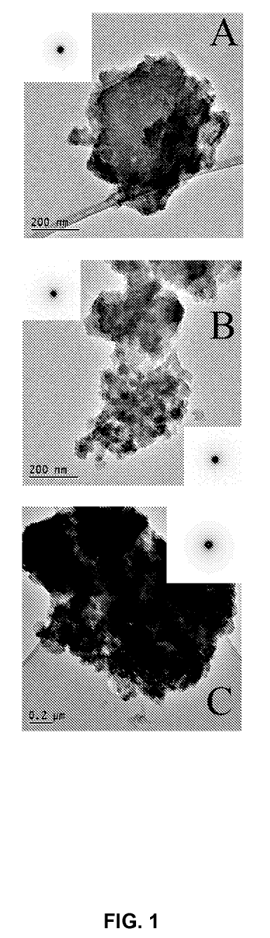

An indurated, hardpan is frequently observed within late Holocene beach ridges in strandplains adjacent to Lake Superior. The clay fraction of selected samples of hardpans from three beach ridge sequences adjacent to Tahquamenon Bay, Mich., Au Train, Mich., and Batchawana Bay, Ontario were studied using TEM techniques to determine the nature of particle texture, chemical composition, and formation and alteration processes. Clay particles were found to be diverse in both texture and chemical composition. Common textures observed include sponge-like textures, platy textures and more rarely spherical textures, in addition to other minor textures. These minor textures are shown in FIGS. 1-3.

FIG. 1 shows examples of TEM images of platy particles. Part (A) shows a TEM image of a pseudo-hexagonal particle with a diameter of approximately 0.5 μm. It appears that selected area electron diffraction (SAED) shows no diffraction spots indicating that the particle is amorphous. Part (B) shows an aggregate of platy particles of different sizes. The larger particle near the top center of the image is approximately 0.3 μm in diameter. Individual, smaller particles below it are approximately 20 nm in diameter. SAED is from larger particle and indicates the particle is amorphous. Part (C) shows a large aggregate of platy particles having a diameter of approximately 1.5 μm. SAED is from the center of the image and indicates the aggregate is amorphous.

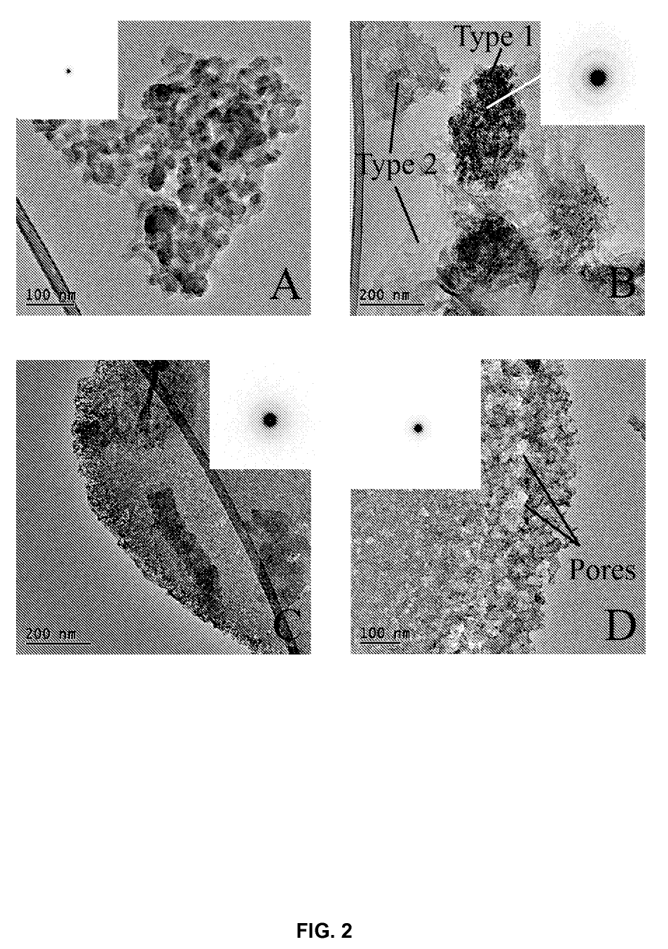

FIG. 2 also shows multiple TEM images. Part (A) shows a TEM image of type 1 sponge-like texture with an SAED pattern showing no crystallinity. Part (B) shows a TEM image of type 1 (dark, high contrast) and type 2 (gray, low contrast) sponge-like particles. SAED is from type 1 particle (indicated by the white line). As shown by the weak rings in the pattern, the SAED indicates minor crystallinity. Part (C) shows a TEM image of type 3 sponge-like texture with SAED showing very weak rings. Part (D) shows a TEM image of another type 3 sponge-like particle showing the nature of pores near an edge.

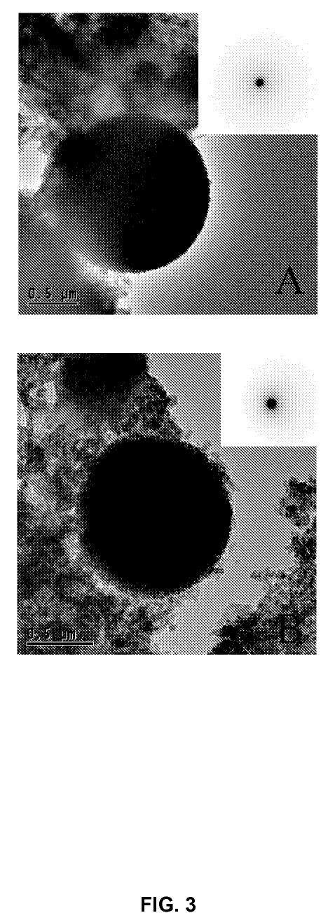

FIG. 3 shows TEM images of spherical particles from Tahquanemon Bay. Both particles (A) and (B) are approximately 1.1 μm in diameter and are composed of smaller particles that can range from about 30 nm to about 70 nm in diameter.

Often, textures of clay particles are diverse and commonly mixed. These textures can be found in similar depositional environments, but yet, separated by several tens of kilometers. Such distance suggests that some systematic mechanisms may be involved in their formation. Chemical compositions of particles varied greatly. Some of the chemical components detected include, but are not limited to, P₂O₅ (about 0.00 to about 1.34 wt %); SiO₂ (about 0.32 to about 58.84 wt %); TiO₂ (about 0.00 to about 1.72 wt %); Al₂O₃ (about 0.11 to about 83.59 wt %); Fe₂O₃ (about 1.07 to about 97.31 wt %), Cr₂O₃ (about 0.00 to about 27.85 wt %); MgO (about 0.00 to about 7.98 wt %); MnO (about 0.00 to about 1.17 wt %); CaO (about 0.00 to about 12.55 wt %); K₂O (about 0.00 to about 0.73 wt %); Na₂O (about 0.00 to about 25.47 wt %); SO₃ (about 0.00 to about 7.45 wt %); and Cl (about 0.00 to about 0.91 wt %). The majority of particles had chemistries dominated by Fe, Al and Si.

III. Synthetic Nanoparticle Soil Material

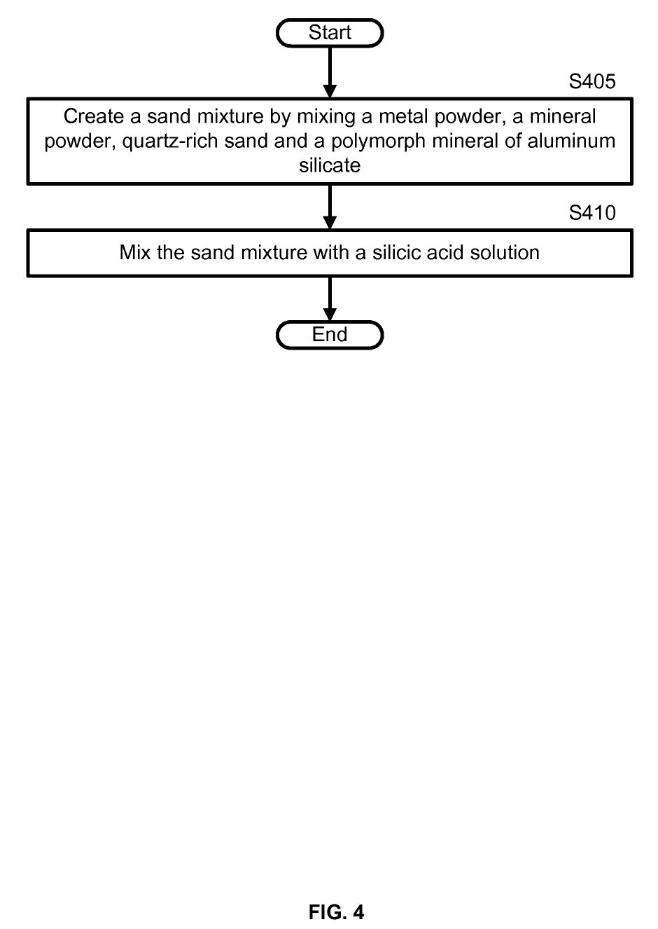

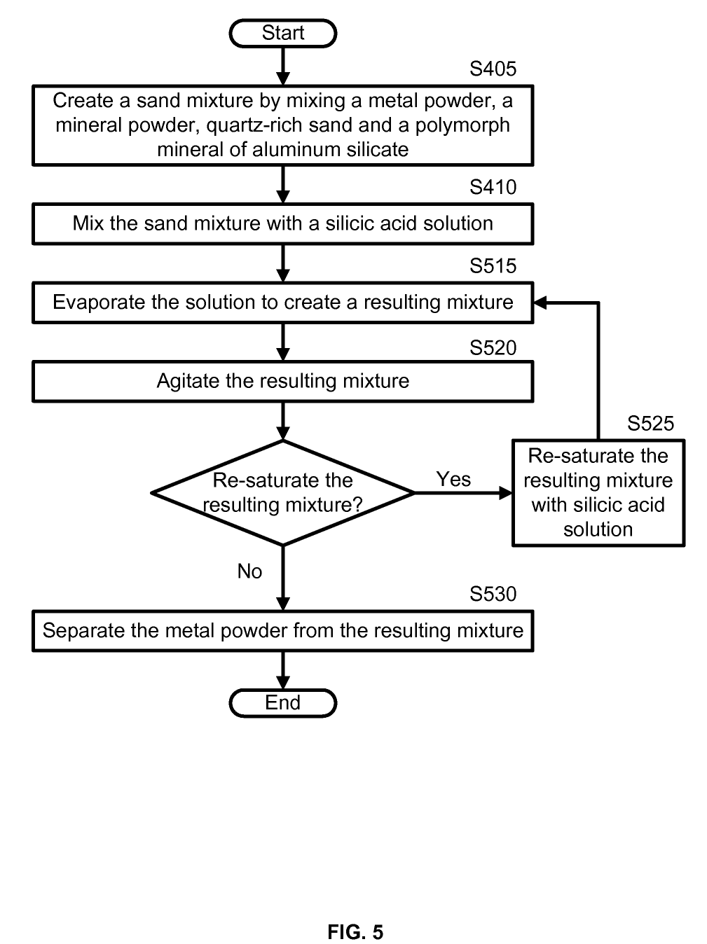

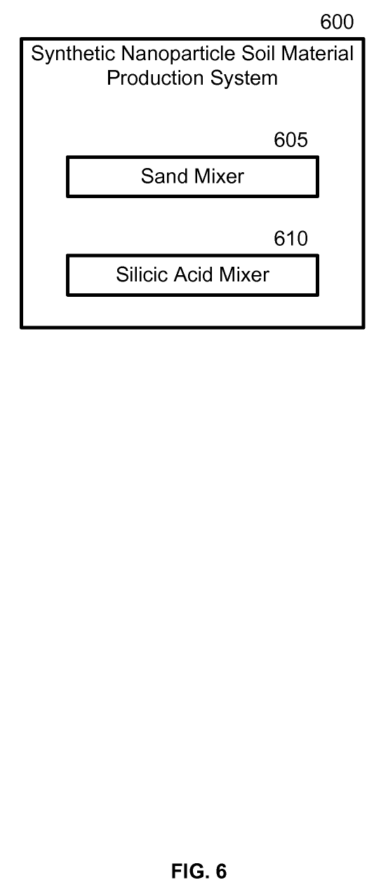

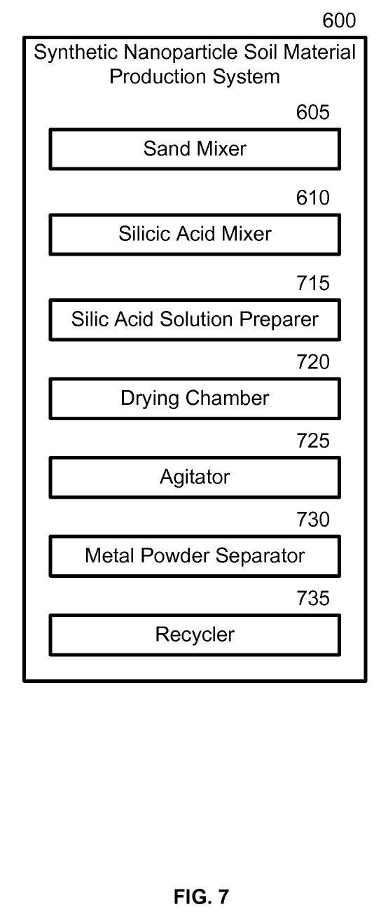

As shown in FIGS. 4, 5, 6 and 7, a synthetic nanoparticle soil material may be produced by using a sand mixer 605 to mix a metal powder, a mineral powder, quartz-rich sand and a polymorph mineral of aluminum silicate S405. The mixture created may be referred to as a sand mixture. Using a silicic acid mixer 610, the sand mixture may be mixed with a silicic acid solution S410. The resulting mixture may be a slurry. This production (and the following steps) may be accomplished using a synthetic nanoparticle soil material production system 600.

The synthetic nanoparticle soil material may comprise about 0.5% to about 20% metal powder by mass, and about 0.5% to about 30% mineral powder by mass. About 0.5% includes any metal powder mass percentage from at least 0.45%. Similarly, about 0.5% includes any mineral powder mass percentage from at least 0.45%. About 20% includes any metal powder mass percentage up to 20.5%. Likewise, about 30% includes any mineral powder mass percentage up to 30.5%. Both metal powder and mineral powder are mixed with quartz-rich sand and a polymorph mineral of aluminum silicate, where the ratio of the quartz-rich sand to the polymorph mineral of aluminum silicate can be 1:99 to 99:1. This combination may form the sand mixture, which is to be mixed with silicic acid solution. The ratio of the sand mixture to the silicic acid solution can be 1:99 to 99:1.

Metal powder is defined to include any iron powder or manganese powder. The iron powder may generate iron oxides. Similarly, the manganese powder may generate manganese oxides.

Mineral powder is defined to include any oxide mineral or hydroxide mineral, derivatives of each, and alternatives. As one embodiment, the mineral powder is hematite (Fe₂O₃). Adding hematite may achieve natural color. Like other Fe-oxide minerals that have been recognized in the sorbtion of phosphate, hematite may also absorb phosphate.

As another embodiment, oxide minerals and their derivatives may be used as the mineral powder to develop the synthetic nanoparticle soil material. Nonlimiting examples include other minerals from the hematite group (e.g., corundum, cassiterite, rutile, etc.); minerals from the ilmenite series (e.g., ulmenite, geikielite, pyrophanite, etc.); minerals from the spinal series (e.g., spinel, hercynite, gahnite, galaxite, etc.); minerals from the magnetite series (e.g., magnetite, magnesioferrite, franklinite, jacobsite, trevorite, brunogeirite, cuprospinel, etc.); romanechite (BaMnMn₈O₁₆(OH₄)); pyrolusite (MnO₂); todorokite ((Mn, Ca, Mg)Mn₃O₇.H₂O); and birnessite ((Na, Ca, K)ₓ(Mn⁴⁺, Mn³⁺)₂O₄.1.5(H₂O)).

As another embodiment, hydroxide minerals and their derivatives may also be used as the mineral powder to develop the synthetic nanoparticle soil material. In particular, alternatives include hydroxide minerals and their derivatives, such as AlOOH minerals, FeOOH minerals and MnOOH minerals. Nonlimiting examples of AlOOH minerals include diaspore, gibbsite and boehmite. Nonlimiting examples of FeOOH minerals include goethite and lepidicrocite. Nonlimiting examples of MnOOH minerals include manganite and groutite.

The quartz-rich sand can comprise a multitude of grain sizes, ranging from very coarse sand to fine clay. It is an embodiment of the present invention to combine a polymorph mineral of aluminum silicate with quartz-rich sand because of the permeability properties of quartz sand and the aluminum silicate's affinity to adhere to quartz grains. The aluminosilicate polymorph mineral can be any mineral selected from among the following: kyanite, andalusite, sillimanite, mullite or variants of each of these minerals. Generally, aluminum in a variety of silicate minerals is known to sorb phosphate. Like the quartz-rich sand, the polymorph mineral of aluminum silicate can also comprise a multitude of grain sizes, ranging from very coarse sand to fine clay.

In one embodiment, kyanite is selected as the aluminosilicate polymorph mineral. Kyanite has a high proportion of aluminum. It is also known to have a relatively low solubility in water.

Alternatively, substitutes for the aluminosilicate polymorph minerals may also be selected. In an embodiment, substitutes include calcium silicates, such as wollastonite and grossular.

The silicic acid solution can be prepared by mixing silicic acid powder with water. Water is defined as deionized water, freshwater, groundwater, brackish water compositions or water in similar compositions. Preparation may be accomplished by using a silicic acid solution preparer 710. The ratio of the silicic acid powder to the water can range from 1:99 to 99:1.

After mixing the sand mixture with the silicic acid solution, a drying chamber 720 may be used to evaporate the silicic acid solution from the slurry S515. The purpose of evaporation is to create a resulting mixture. Evaporation may take on several connotations. In one embodiment, evaporation may refer to aging the resulting mixture overtime. In another embodiment, evaporation may refer to drying the resulting mixture. Timewise, depending on the amount of heat used, it may take seconds, minutes, hours, days or even months (e.g., 1-2 months) for the evaporation process to be completed or completed at a level desired by a user.

Following evaporation, the resulting mixture may be agitated S520. Agitation may be achieved by using an agitator 725, such as a concrete mixture, a bin mixer, etc. Additionally, the agitated resulting mixture may be re-saturated with the silicic acid solution S525. Re-saturation may be repeated as often as necessary or desired. Where re-saturation takes place, the cycle of evaporation and agitation may be repeated.

The metal powder from the resulting mixture may also be mechanically separated S530. This separation may be achieved by using a metal powder separator 730. The metal powder separator 730 may parse the metal powder according to grain size with the aid of sieves (e.g., woven wire sieves) or by magnetic separation. Aperture sizes for sieves may range, for example, from 5 mm to <38 μm. Using a recycler 735, separated metal powder may be recycled and reused to make additional synthetic nanoparticle soil materials.

IV. Properties of Starting Materials

Scanning electron microscopy (SEM) may be performed on the starting materials using a variable pressure SEM. Samples to be observed may be placed on carbon dots and investigated under high vacuum. Images may be captured electronically.

The Fe powder in the synthetic soil is commonly unoxidized or partially oxidized. Often, the Fe powder is visible in the images as white grains. Fe powder grains are commonly approximately 100 μm to approximately 5.0 μm in diameter. Moreover, Fe oxide grains are commonly equant.

In one embodiment, the polymorph mineral of aluminum silicate is kyanite. A blue crystal, kyanite can expand irreversibly when heated. The degree of volume expansion may depend upon the mesh size. An advantage of such expansion is that expansion can offset shrinkage of other raw materials and binders employed in a mixture. Examples of kyanite specifications may be obtained from Kyanite Mining Corporation of Dillwyn, Va.

SEM of the synthetic soil with kyanite may indicate that the material has distinct texture. Often, kyanite grains dominate images and have a pseudo rectangular morphology. In many grains, the triclinc nature of kyanite is evident with crystallographic angles α≠β≠γ. Maximum diameters of individual kyanite particles may vary from approximately 100 μm to approximately 0.05 μm. Particles that are approximately 15 μm to approximately 3 μm in diameter tend to be more elongated in morphology. Particles that are less than 3 μm in diameter also tend to be elongated. However, they seem to become more equant in shape.

Kyanite grains tend to have a strong affinity to adhere to larger quartz grains. This property helps explain apparently low totals in the <38 μm fraction in the grain size data for kyanite-rich matieral, and may explain the comparatively high values of coefficients of conductivity (k) for material with 10% kyanite powder.

Illustrating various grain sizes of kyanite, the following figures may be considered.

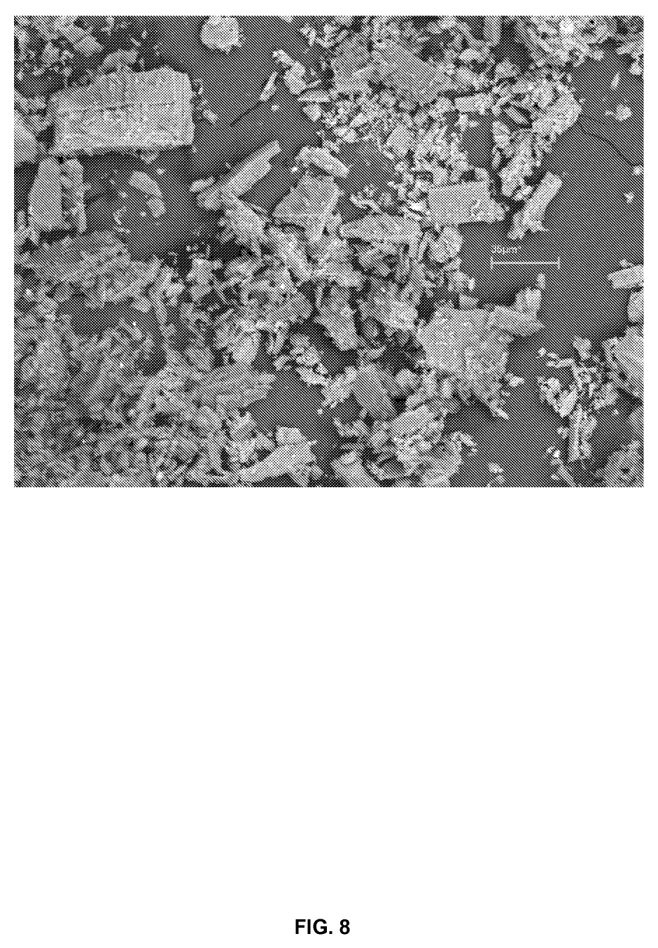

FIG. 8 shows an SEM image of synthetic soil with a high proportion of kyanite. Kyanite grains dominate the image and have a pseudo rectangular morphology. Sizes of particles in this image vary from approximately 50 μm to approximately 0.3 μm. Smaller particles tend to be more elongated in morphology. In larger grains, the triclinc nature of kyanite is evident with angles α≠β≠γ.

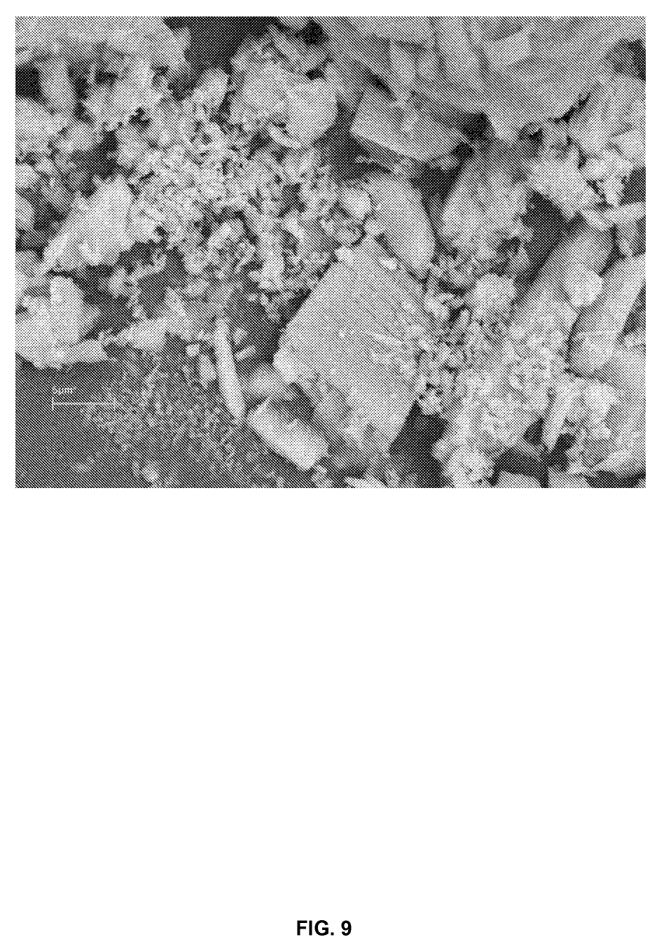

FIG. 9 shows an SEM image of the synthetic soil with a high proportion of kyanite with lesser amounts of Fe-oxide material. Kyanite grains dominate the image and have a pseudo rectangular morphology. Sizes of particles in this image vary from approximately 50 μm to approximately 0.05 μm. A cluster of nanoparticle-sized material is located immediately to the right of the scale bar. Smaller particles tend to be somewhat more elongated in morphology although very small particles (<0.5 μm) seem equant in shape. In larger grains, the triclinc nature of kyanite appears evident with angles α≠β≠γ.

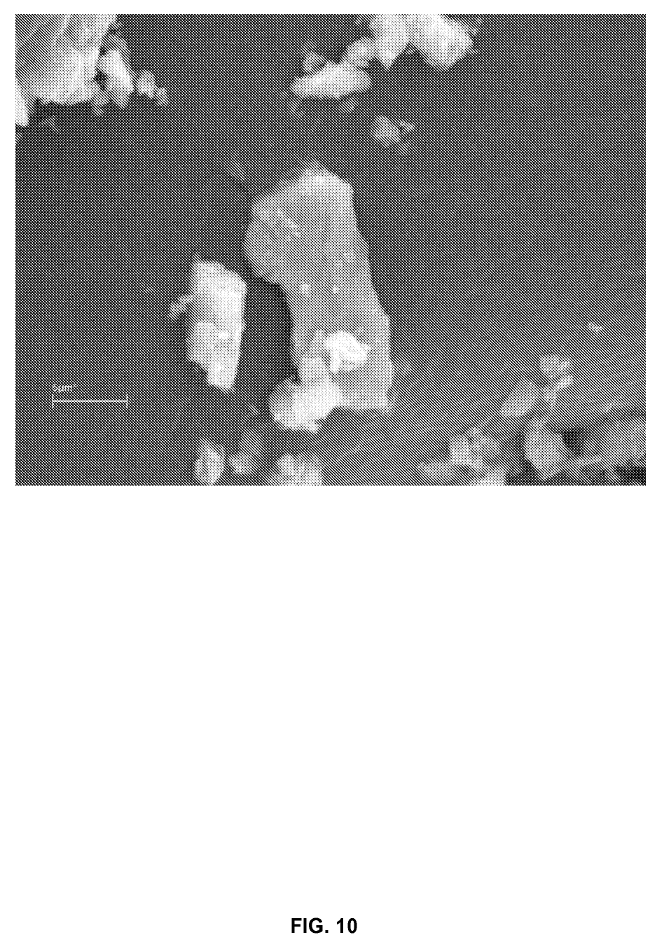

FIG. 10 shows an SEM image of the synthetic soil with a high proportion of kyanite with lesser amounts of Fe-oxide material showing isolated grains. The two larger grains are kyanite grains that appear to dominate the image and have a pseudo rectangular morphology. Sizes of particles in this image vary from approximately 18 μm to approximately 0.05 μm. This image shows the variability of morphology of kyanite grains. The larger grain on the left shows the common straight crystal edge and face morphology. In this grain, the triclinc nature of kyanite is evident with angles α≠β≠γ. The larger grain in the center of the image shows more curvilinear edges consistent with the crushing/grinding processes involved in production at the source. Smaller particles (e.g., <1.0 μm) tend to be somewhat more elongated in morphology.

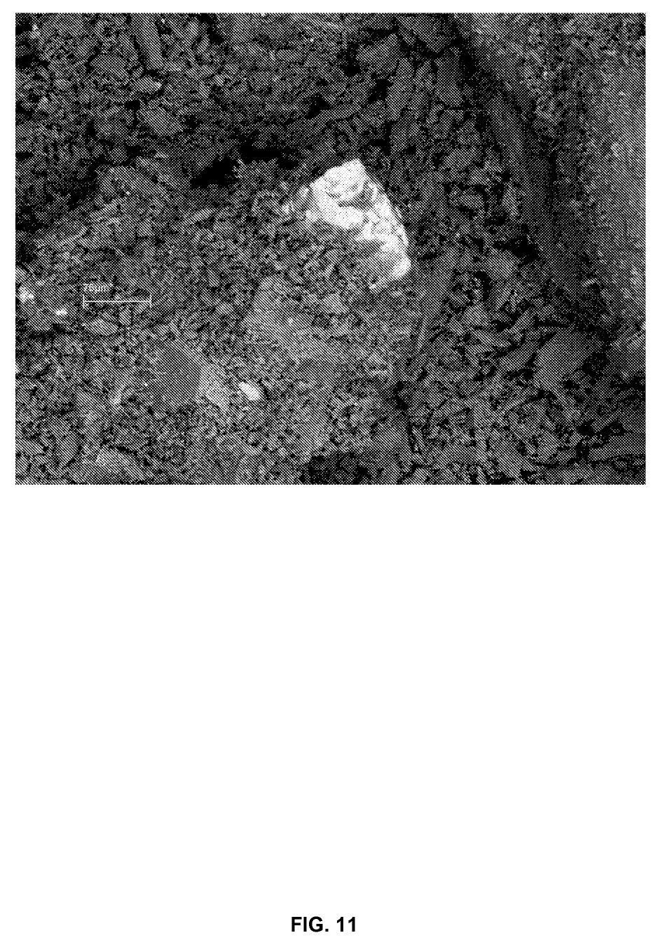

FIG. 11 shows an SEM image of the synthetic soil with a high proportion of kyanite. Kyanite grains appear to dominate the image and have a pseudo rectangular morphology. Sizes of most kyanite particles in this image vary from approximately 100 μm to approximately 2.0 μm. A large grain of quartz is found in the upper right hand corner and is covered with clay sized kyanite. The large bright grain in the center of the image is a partially oxidized fragment of iron powder approximately 100 μm in diameter.

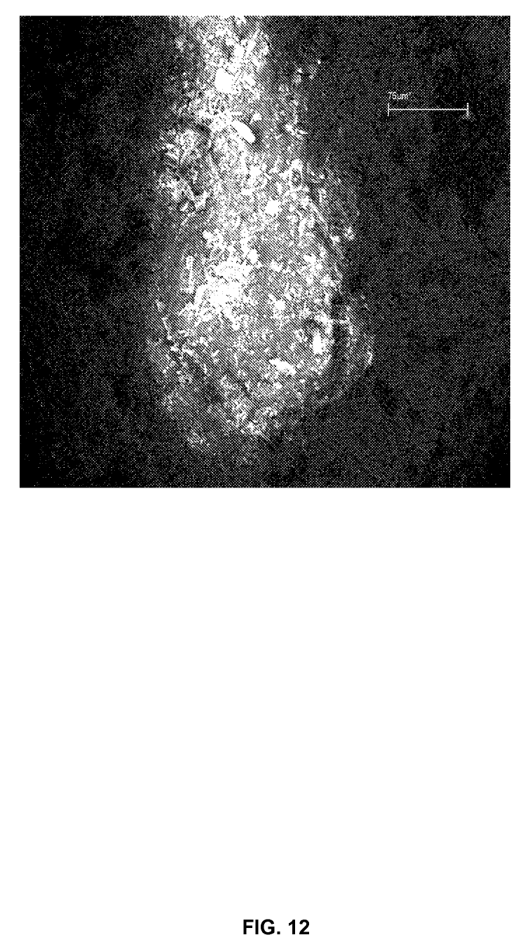

FIG. 12 shows an SEM image of the synthetic soil with a high proportion of kyanite with lesser amounts of Fe-oxide material. Kyanite grains appear to dominate the image and have a pseudo rectangular morphology. Grains have adhered to a large quartz grain and charging (white) appears evident resulting form poor conduction.

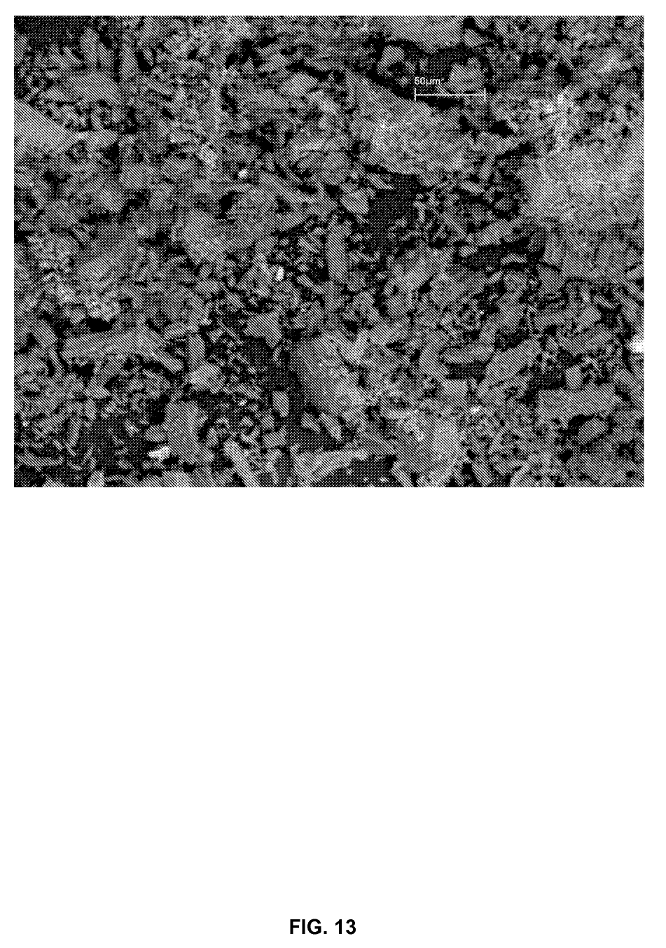

FIG. 13 shows an SEM image of the synthetic soil with a high proportion of kyanite. Kyanite grains appear to dominate the image and have a pseudo rectangular morphology. Sizes of particles in this image vary from approximately 50 μm to approximately 1.0 μm. In larger grains, the triclinc nature of kyanite appears evident with angles α≠β≠γ. White grains are iron powder fragments having a size approximately 5.0 μm to approximately 10.0 μm in diameter.

In another embodiment, other polymorph minerals of aluminum silicate that may be used include andalusite and sillimanite. Andalusite is a mineral that is usually gray and may be often found with symmetrically arranged white or black areas. Sillimanite is a mineral that may be brown, gray or white. Andalusite and sillimanite share common structural features with kyanite. In all three minerals, straight chains of edge-sharing AlO₆ octahedra extend along the c axis. These octahedral may contain half of the Al in the structural formula. Each mineral differs in the remaining Al atoms: 6-fold-sites in kyanite; 5-fold sites in andalusite; and 4-fold sites in sillimanite. These Al-polyhedra may alternate with the SiO₄ tetrahdra, which is also along the c axis, and may link together the AlO₆ chains.

Kyanite differs from andalusite and sillimanite in that kyanite is about 14% denser than andalusite and about 11.5% denser than sillimanite. It can be expected that kyanite is stable at the highest pressures and lowest temperatures. In contrast, andalusite is stable at the low pressure phase. Sillimanite is stable at moderate pressures and high temperatures.

In another embodiment, the aluminosilicate polymorph mineral is mullite. Mullite has a structure similar to that of sillimanite. In sillimanite, the Al in the 4-fold tetrahedral sites and the SiO₄ tetrahedra may be linked by corners to form double chains of tetrahedral parallel to the c axis. These chains may provide lateral linkage between AlO₆ chains. In mullite, extra Al may substitute for Si in the tetrahedral chains. To chemically balance, each substitution may require removing some O atoms according to the scheme 2Al³⁺+x=2Si⁴⁺+O²⁻, where x represents a vacant oxygen site. Examples of mullite specifications may also be obtained from Kyanite Mining Corporation of Dillwyn, Va.

Grain size analysis may be performed on a representative coarse grained version, as well as a representative fine grained version, of the technology. Grain size determination may be accomplished using mechanical sieves. For example, for each version, approximately 200 grams of raw material may be analyzed using 8″ sieves having fractions between 1400 μm and 38 μm. The percentage that passed the 38 μm sieve was included in the analysis. Sieve stacks were shaken mechanically for 30 minutes. Fractions captured in each sieve were then weighed. Normalized percentages of each size fraction were calculated based on the total sum of mass retained in each sieve.

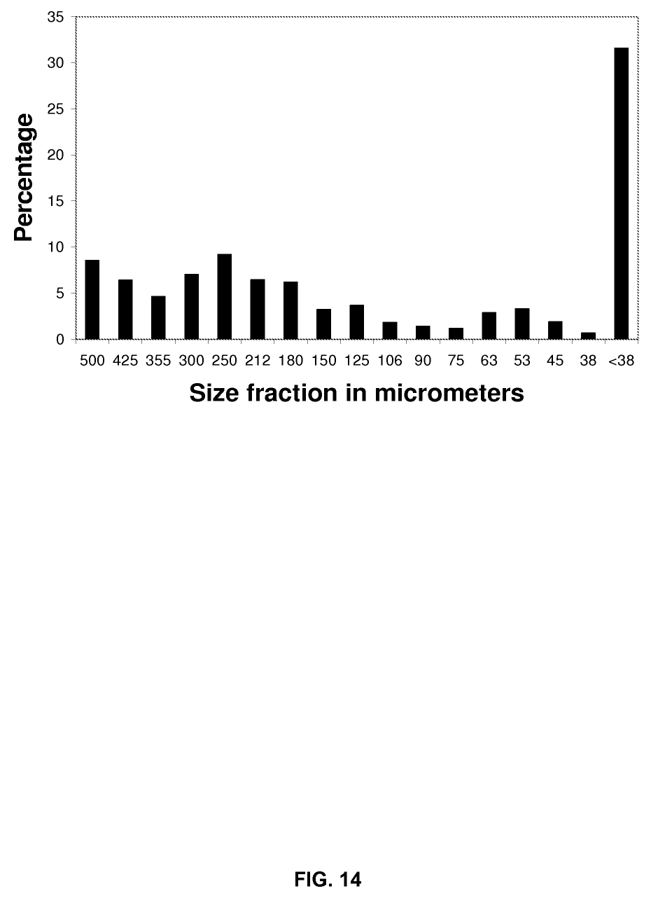

Grain size analysis indicates that for most sample material, a single normal distribution of particles does not exist in the starting material. For the fine grain sample, as shown in FIG. 14, approximately 70% of the material consists of kyanite powder by volume. However, approximately 31.58% of the mass passed through the 38 μm sieve. This discrepancy can be explained by adhesion of fine grained kyanite to other grains.

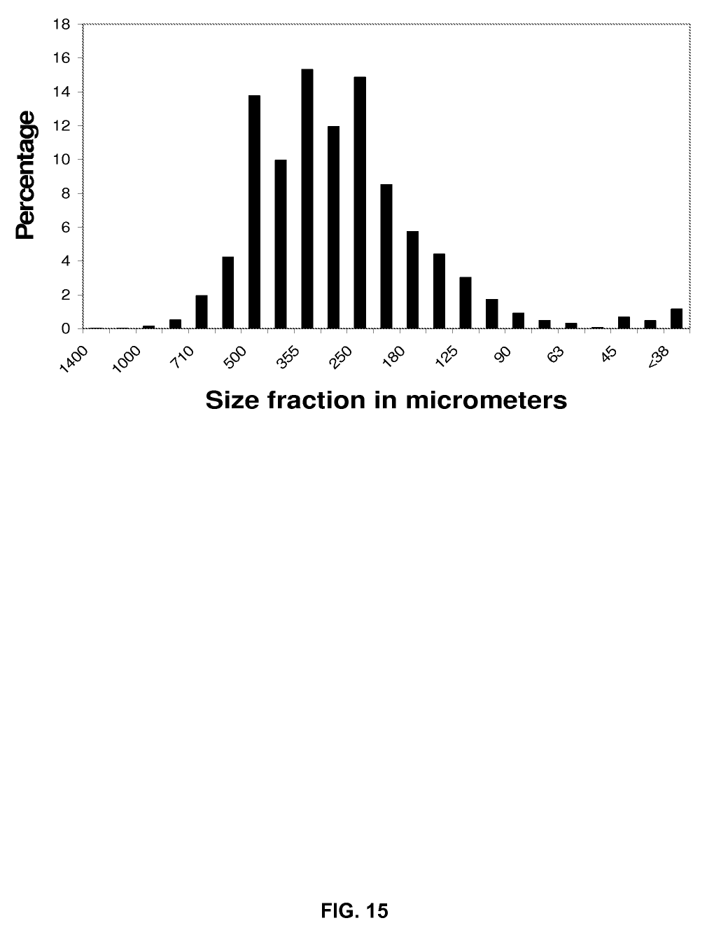

In contrast, as shown in FIG. 15, coarse material had approximately 1.13% passing through the 38 μm sieve. This small fraction indicates that a significant amount of kyanite powder material is also adhered to grains in this version of the synthetic soil.

It is important to note that the grain size analysis shown here is not limited to the size ranges. Rather, those shown here are representative of the grain sizes that would be most commonly used in the applications of the technology. These results show that grain size can be scaled to meet specifications.

V. Permeability

The permeability (i.e., coefficient of hydraulic conductivity) constants may be determined on samples that represent a range of the synthetic soil. Permeability measurements may be conducted using a permeameter, such as a E-216 Combination permeameter from Geotest Instrument Corp., Evanston, Ill. A falling head assembly method may be used. The values of k (i.e., hydraulic conductivity) may be calculated by using a modification of the Darcy equation:
k=[(Q×L)/13.76(h₀−h₁)]×Log₁₀(h₀/h₁) (1)
where k=coefficient of hydraulic conductivity (cm/s); Q=flow in ml; L=length of sample in cm; t=total time of flow in seconds; and h₀=final height of water column above chamber outflow in cm. The cross-sectional area of the unit used can be 31.65 cm². Different permutations of the Darcy equation exist and are known in the art.

In experiments done on four variations of the synthetic soil, the coefficient of hydraulic conductivity (k) as shown in TABLE 1 below varied from about 0.022 cm/s to about 2.0×10⁻⁶ cm/s. Standard deviation of all measurements of all variations investigated resulted in about 0.008. In three experiments, flow appeared to stop. Thus, flow is estimated to be as low as about 1.0×10⁻⁸ cm/s or lower. As more kyanite powder is added to the media the coefficient of hydraulic conductivity (k) becomes lower. This lowering is evident in considering variations of the synthetic soil that had appreciable kyanite (e.g., 10% or greater).

TABLE 1
Values and Parameters Used to Calculate the Coefficient of Hydraulic Conductivity (k)

| | t | h₀ | h₁ | vol₀ | vol₁ | Q | L | h₀ − h₁ | h₀/h₁ | log₁₀ h₀/h₁ | k |
|---|---|---|---|---|---|---|---|---|---|---|---|
| | s | cm | cm | ml | ml | ml | cm | cm | cm | cm | cm/s |
| 1A | 30.0 | 60.6 | 46.5 | 19.4 | 46.1 | 26.7 | 7.4 | 14.1 | 1.30323 | 0.115019671 | 0.0039 |
| Medium | 42.2 | 66.3 | 27.6 | 10.0 | 76.2 | 66.2 | 7.4 | 38.7 | 2.40217 | 0.380604446 | 0.0083 |
| <1% kyanite | 43.3 | 70.5 | 26.5 | 2.8 | 77.2 | 74.4 | 7.4 | 44.0 | 2.660 | 0.424943243 | 0.00892 |
| | 49.6 | 71.9 | 25.2 | 0.0 | 79.2 | 79.2 | 7.4 | 46.7 | 2.85317 | 0.45532835 | 0.00837 |
| | 50.3 | 68.7 | 23.6 | 5.0 | 82.5 | 77.5 | 7.4 | 45.1 | 2.91102 | 0.464044734 | 0.00853 |
| | 55.4 | 71.9 | 21.6 | 0.0 | 86.0 | 86.0 | 7.4 | 50.3 | 3.3287 | 0.522275139 | 0.00867 |
| | 45.3 | 71.9 | 24.2 | 0.0 | 81.4 | 81.4 | 7.4 | 47.7 | 2.97107 | 0.472913524 | 0.010 |
| | 58.8 | 71.9 | 20.5 | 0.0 | 87.9 | 87.9 | 7.4 | 51.4 | 3.50732 | 0.544975029 | 0.00852 |
| | 35.5 | 71.9 | 25.5 | 0.0 | 79.1 | 79.1 | 7.4 | 46.4 | 2.820 | 0.45018871 | 0.01163 |
| | 32.2 | 71.9 | 26.7 | 0.0 | 76.2 | 76.2 | 7.4 | 45.2 | 2.69288 | 0.43021763 | 0.01211 |
| 1C | 22.0 | 79.3 | 30.7 | 0.0 | 83.2 | 83.2 | 7.8 | 48.6 | 2.58306 | 0.412134812 | 0.01818 |
| Coarse | 15.7 | 79.3 | 39.5 | 0.0 | 67.4 | 67.4 | 7.8 | 39.8 | 2.00759 | 0.302676092 | 0.01851 |
| 10% kyanite | 14.2 | 79.3 | 43.4 | 0.0 | 60.7 | 60.7 | 7.8 | 35.9 | 1.82719 | 0.261783458 | 0.01767 |
| | 14.7 | 79.3 | 39.1 | 0.0 | 68.1 | 68.1 | 7.8 | 40.2 | 2.02813 | 0.30709643 | 0.020 |
| | 20.7 | 79.3 | 27.1 | 0.0 | 89.2 | 89.2 | 7.8 | 52.2 | 2.9262 | 0.466303896 | 0.02182 |
| | 16.1 | 79.3 | 38.6 | 0.0 | 69.0 | 69.0 | 7.8 | 40.7 | 2.0544 | 0.312685883 | 0.01866 |
| | 15.6 | 79.3 | 37.5 | 0.0 | 70.8 | 70.8 | 7.8 | 41.8 | 2.11467 | 0.32524192 | 0.020 |
| | 21.6 | 79.3 | 27.9 | 0.0 | 87.2 | 87.2 | 7.8 | 51.4 | 2.84229 | 0.453668984 | 0.020 |
| | 24.5 | 79.3 | 23.7 | 0.0 | 96.0 | 96.0 | 7.8 | 55.6 | 3.34599 | 0.524524841 | 0.02095 |
| | 22.7 | 79.3 | 25.5 | 0.0 | 93.3 | 93.3 | 7.8 | 53.8 | 3.1098 | 0.492733007 | 0.02134 |
| 1D | 385.0 | 51.3 | 47.5 | 47.0 | 54.0 | 7.0 | 7.2 | 3.8 | 1.08 | 0.033423755 | 8.4E−05 |
| 30% kyanite | 88.4 | 47.5 | 46.1 | 54.0 | 56.3 | 2.3 | 7.2 | 1.4 | 1.03037 | 0.012992684 | 0.00013 |
| | 130.2 | 56.3 | 44.7 | 56.3 | 59.1 | 2.8 | 7.2 | 11.6 | 1.25951 | 0.100200872 | 9.7E−05 |
| | 108.2 | 44.7 | 43.2 | 59.1 | 61.2 | 2.1 | 7.2 | 1.5 | 1.03472 | 0.014823776 | 0.0001 |
| | 101.2 | 43.2 | 41.8 | 61.2 | 63.1 | 1.9 | 7.2 | 1.4 | 1.03349 | 0.014307465 | 0.0001 |
| | 90.0 | 41.8 | 41.0 | 63.1 | 65.0 | 1.9 | 7.2 | 0.8 | 1.01951 | 0.008392425 | 0.00012 |
| | 182.7 | 41.0 | 38.7 | 65.0 | 68.4 | 3.4 | 7.2 | 2.3 | 1.05943 | 0.025072892 | 0.00011 |
| | 122.8 | 38.7 | 37.1 | 68.4 | 71.4 | 3.0 | 7.2 | 1.6 | 1.04313 | 0.018337055 | 0.00015 |
| | 140.2 | 37.1 | 35.6 | 71.4 | 73.7 | 2.3 | 7.2 | 1.5 | 1.04213 | 0.017923912 | 0.0001 |
| | 346.4 | 35.6 | 33.2 | 73.4 | 79.0 | 5.6 | 7.2 | 2.4 | 1.07229 | 0.030311914 | 0.00011 |
| 1E* | 147600 | 61 | 20.2 | 0.0 | 69.9 | 69.9 | 7.7 | 40.8 | 3.0198 | 0.479978466 | 3.1E−06 |
| 70% kyanite | 154800 | 72.1 | 30.2 | 0.0 | 72.2 | 72.2 | 7.7 | 41.9 | 2.38742 | 0.377928322 | 2.4E−06 |
| | 140400 | 80.2 | 55.4 | 0.0 | 68.8 | 68.8 | 7.7 | 24.8 | 1.44765 | 0.160664604 | 1.8E−06 |
| | 145800 | 65.9 | 23.2 | 0.0 | 69.4 | 69.4 | 7.7 | 42.7 | 2.84052 | 0.45339743 | 2.8E−06 |
| | 147600 | 69.3 | 21.5 | 0.0 | 70.1 | 70.1 | 7.7 | 47.8 | 3.22326 | 0.508294775 | 2.8E−06 |
| | | | | | | | | | | Maximum | 0.02182 |
| | | | | | | | | | | Minimum | 1.8E−06 |
| | | | | | | | | | | St. Dev | 0.00838 |

The star (*) denotes that three trials were done where flow appears to stop indicating that k values exist for this material. The k values for these trials are estimated to be less than 1E-08.

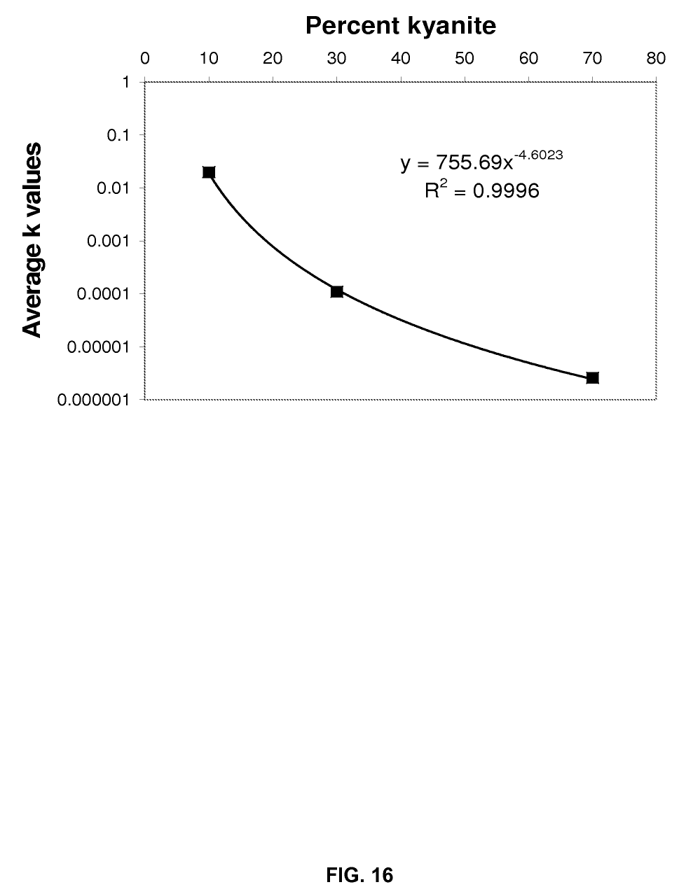

As shown in FIG. 16, an empirical relationship for the samples studied is observed which can be expressed as a power function denotable as y=755.69x^{-4.6023} The X-Y logarithm-linear plot illustrates an empirical relationship between the percent kyanite in the technology and the averages of the coefficient of hydraulic conductivity (k) values determined for three samples (1C, 1D, 1E) from TABLE 1. The dramatic drop in permeability may be attributed to the small particle size of kyanite in combination with the tabular or blade-like morphology of the mineral.

Investigations of the permeability of the synthetic soil indicate that the synthetic soil can be adjusted to meet flow velocity criteria for a wide range of applications. For example, a low flow velocity may be highly desired in constructed wetland applications. In contrast, a higher flow velocity may be more useful for industrial applications involving higher volumes of wastewater treatment.

VI. Experiments

The particles produced by the process are similar to those observed in natural ortsteins and hydromorphic soils. Typically, round, platy and sponge-like particles are present.

Silicon occurring in iron oxyhydroxides may have the net effect of reducing the overall crystallinity of the minerals. To inhibit crystallinity and thus promote higher reactivity, solutions of silicic acid may be used. Such solutions may serve as the key to this process.

For illustrative purposes, a saturated solution of silicic acid H₄SiO₄ (A288) may be prepared by introducing 0.72 g of H₄SiO₄ powder per 1 liter of deionized water. It is possible that a small volume of the acid does not dissolve. When this effect occurs, it tends to indicate that the solution is saturated.

In this illustrative example, the measured pH of the starting solution of silicic acid is 7.28. A mixture of 1.5 grams of Fe-powder <100 mesh (I60) may be added to 150 grams of a quartz rich sand, such as Ottawa sand. The silicic acid solution may be introduced so to cover the top of the Fe powder and sand mixture. The solution can be allowed to evaporate over a certain period, (e.g., 1-2 days). The resulting mixture may then be agitated, and another solution may be applied. This saturation process may be repeated (e.g., 4 times). The same process can also be performed at the bench scale using a quartz-rich bagged sand, such as those from a retail store.

A control experiment may be performed by saturating mixtures of Fe powder and sand in beakers with either water (e.g., deioninzed water), silicic acid or a combination of both. The silicic acid experiments consistently produced darker colors similar to approximately 10 YR 4/6.

As the control, the quartz-rich sand may be used. The quartz-rich sand may comprise of sand-size and clay-size particles. The Munsell color of the sand may be approximately 7.5 YR 8/2. After the first saturation, sandy particles appeared to maintain most of its original color at the surface. When agitated, the darker reds and deep browns mixed with the original light colored sand. About 50% of the sandy material may be coated with Fe. The Munsell color description of the sand may be approximately 7.5 YR 4/6 for the Fe coated particles mixed with the original (approximately 7.5 YR 8/2). Corresponding chemical data for clay particles of this treatment generally indicates the weight percentages for the Si, Fe, and O-content were about 2.90% of Si, about 86.74% of Fe, and about 10.36% of O.

The second saturation process tends to show a dramatic change. The color of the sand may change to about 7.5 YR 4/6, which may be homogenous throughout. Small Fe aggregates may begin to form ≦1 cm clumps within the sand. The aggregates may be brittle with a dark, ˜10 YR 3/2, core. Corresponding chemical data for clay particles of this treatment may indicate that the Si-content was about 4.91%, that the Fe-content was about 86.92%, and that the O-content was about 8.17%.

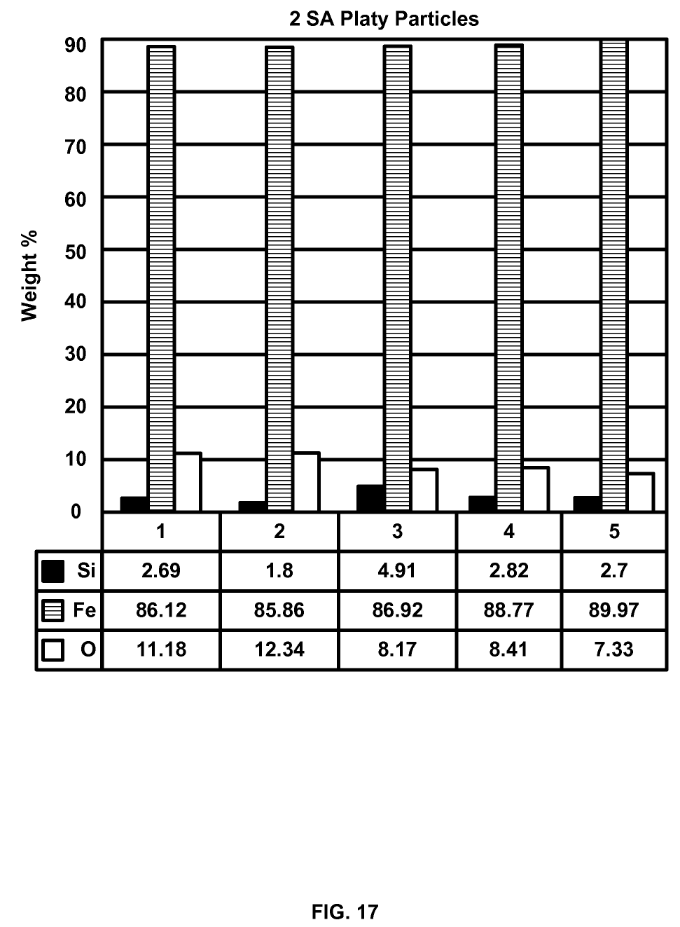

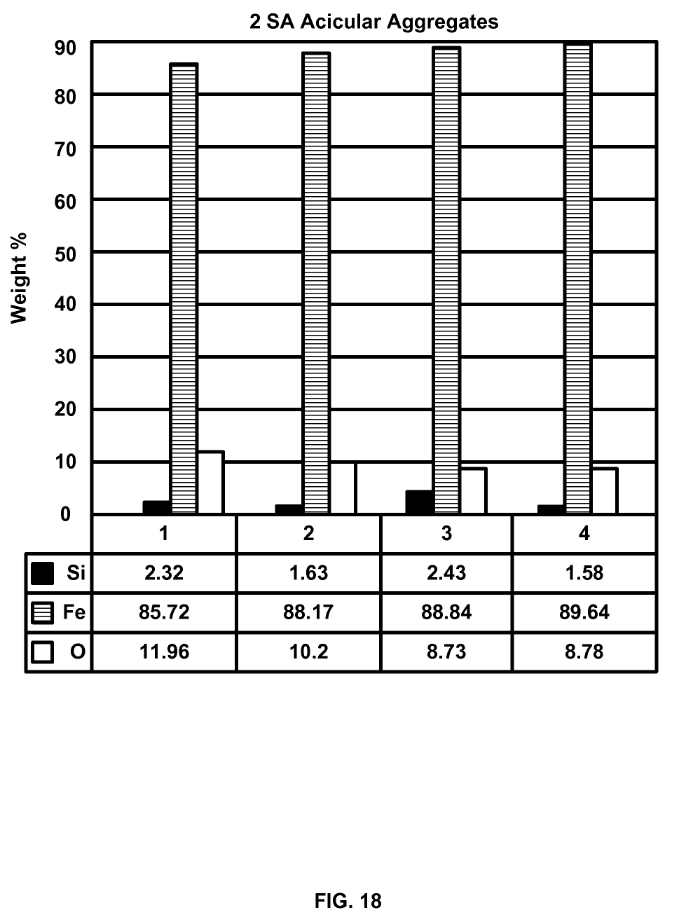

To illustrate the percentages of Si-content, Fe-content, and O-content in certain particles, attention may be turned to FIGS. 17 and 18. FIG. 17 displays a representative bar graph showing the weight percentage of Si, Fe, and O after the 2^{nd} saturation for platy particles. Similarly, FIG. 18 displays a representative graph showing the weight percentage of Si, Fe, and O after the 2^{nd} saturation for acicular particles.

After the third saturation, the color of the sand may develop a rich brown color, ˜10YR 4/4. The Fe aggregates may grow larger, up to about 2 cm clumps that contained the dark inner core. Underneath the microscope, Fe may completely cover the quartz particles, which can be stained orange-red.

The fourth saturation may have a similar outcome as the third saturation process. The color of the soil may continue to develop a richer orange-brown color. The Munsell color may be approximately 10 YR 4/6. Corresponding chemical data for clay particles of this treatment may indicate that the Si-content was about 8.40%, that the Fe-content was about 74.02%, and that the O-content was about 17.58%.

Grain size analysis indicates that Fe powder can be mechanically separated and recycled. This characteristic may enable costs to be reduced as Fe powder is a major cost in the process.

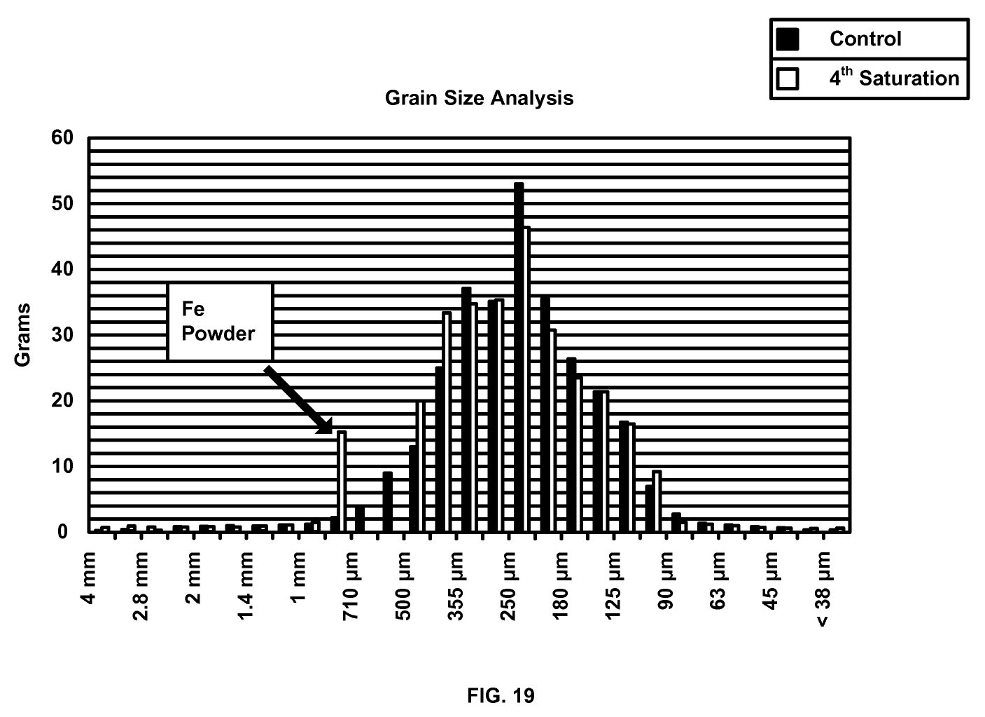

FIG. 19 illustrates grain size distributions for original sand (control) and the 4^{th} saturation. It may be noted that the Fe powder has a distinct distribution from the rest of the sand in the 4^{th} saturation and can be easily separated with mechanical sieves for large scale processing and recycling.

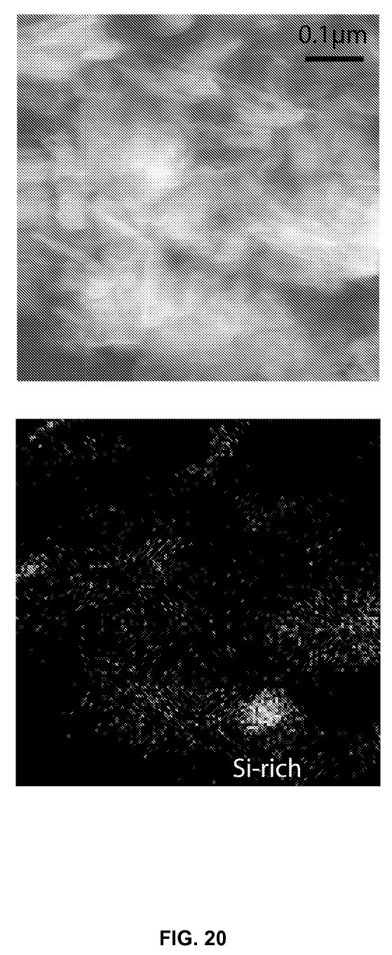

TEM data supporting this saturation process may be shown in FIGS. 20, 21 and 22. These figures capture examples of images, diffraction patterns and chemical mapping.

In particular, FIG. 20 shows an image having a concentration of Si in an Fe particle. The region is approximately 0.1 μm in diameter. Smaller areas which have high concentrations of Si may also be present.

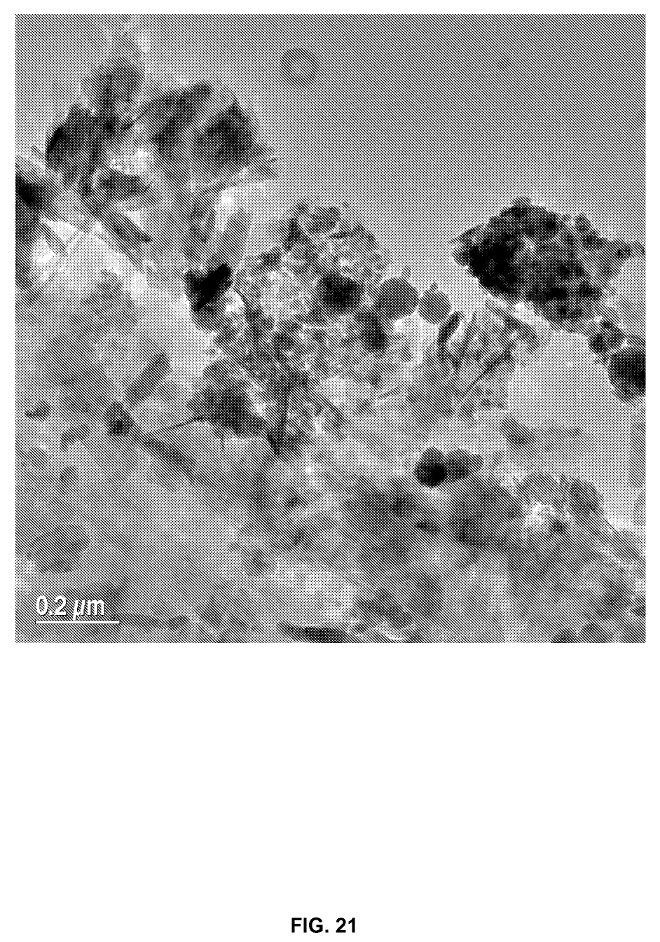

FIG. 21 shows aggregates of poorly crystalline Fe oxide/oxyhydroxide particles along with goethite crystals. Generally, the Fe resembles platy and sponge-like characteristics. The platy and sponge-like particles are commonly about 0.5 μm to about 0.6 μm in maximum dimension. The goethite may form in an acicular habit; its particle size may be about 0.2 μm in length and several nanometers in width.

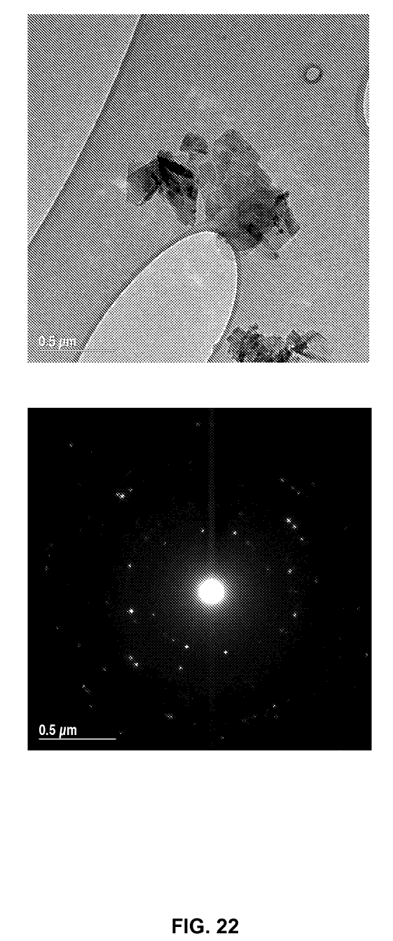

FIG. 22 shows a platy crystalline Fe particle that is about 1.25 μm long and about 0.75 μm wide. The electron diffraction pattern generally shows that the platy Fe particle has a crystalline structure, is an orthorhombic net and has a modified HCP packing.

Iron oxides and oxyhydroxides are known to sorb phosphate from natural freshwaters, estuarine waters or waters similar in composition. Here, phosphorus can occur in the synthetic soil at concentrations up to about 1.34 wt % P₂O₅. Therefore, the synthetic soil produced in this investigation is expected to be very reactive with phosphate.

This characteristic is significant because phosphate is a major pollutant that is often derived from fertilizer use in areas adjacent to major water resources and wetland systems. While created wetland systems may remove this pollution from the environment, using this synthetic soil in the ecosystem can enhance phosphate removal capacity.

Furthermore, based on soil order maps, this technology system is appropriate for use in approximately 35% of the geographic area of the United States. This system is much closer to mimicking natural soils associated with wetlands than many existing substrates. It should be noted that this technology may also be used globally.

Moreover, with respect to costs, the synthetic soil technology is relative cheap to produce. Fe powder, silicic acid, and sand are all comparatively low cost material and are available throughout the United States and Europe. For instance, it may be the case where the element costs are as follows: Fe powder at $126, silicic acid at $217, sand at $25, water at $5, and power (utilities) at $20. The total would be $393 per 1850 kg (˜cubic yard). Yet, costs can even be further reduced by virtue of recycling the Fe powder, silicic acid solutions.

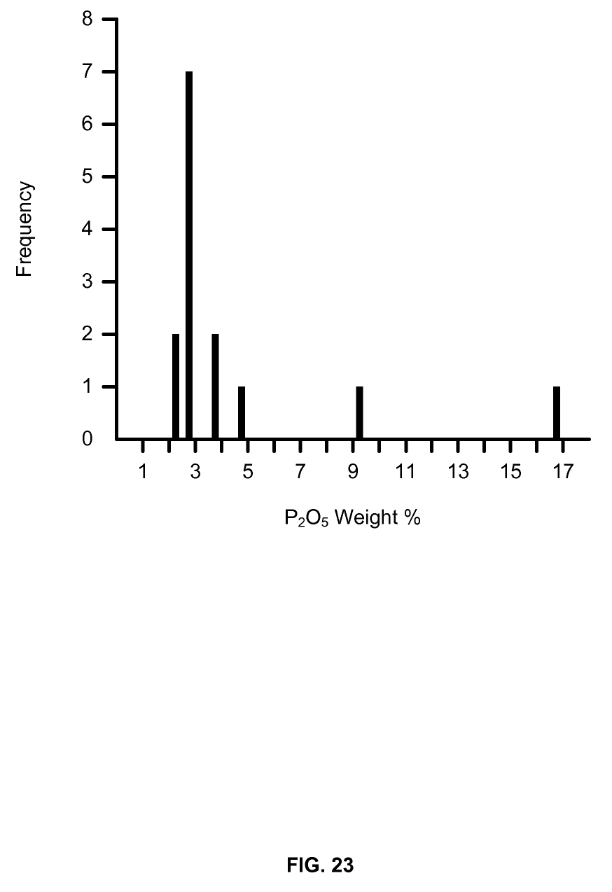

When a polymorph mineral of aluminum silicate is introduced, concentrations of phosphorous absorbed in the synthetic soil dramatically increase. For instance, as shown in FIG. 23, where kyanite is treated with a 1% H₃PO₄ solution for one hour, the maximum concentration of P₂O₅ in clay-sized kyanite-rich particle aggregates can be about 16.64 wt %.

To determine this data through TEM investigation, grain mounts may be prepared using methyl alcohol as a dispersing medium. Samples may be prepared on 300 mesh hole carbon Cu grids. Using a 300 kV JEM 3010 transmission electron microscope, the samples may be investigated by imaging, selected area diffraction, and energy dispersive spectroscopy (EDS).

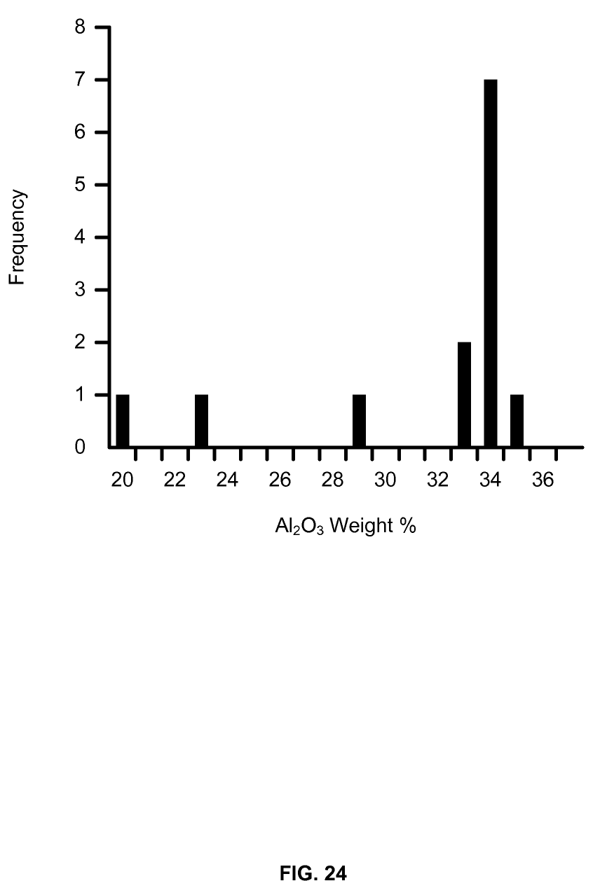

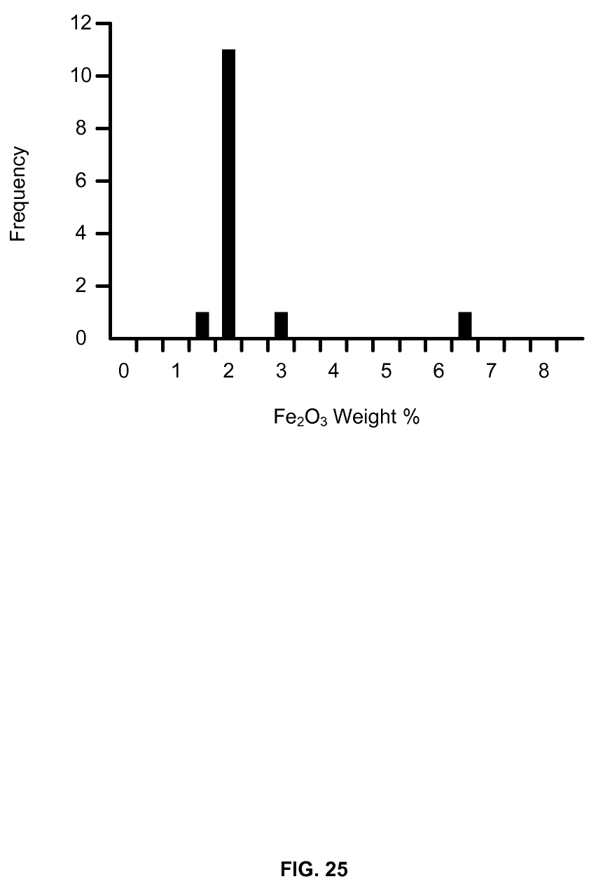

In addition to the P₂O₅ concentrations, Al₂O₃ concentrations (as shown in FIG. 24) and Fe₂O₃ concentrations (as shown in FIG. 25) may also be investigated.

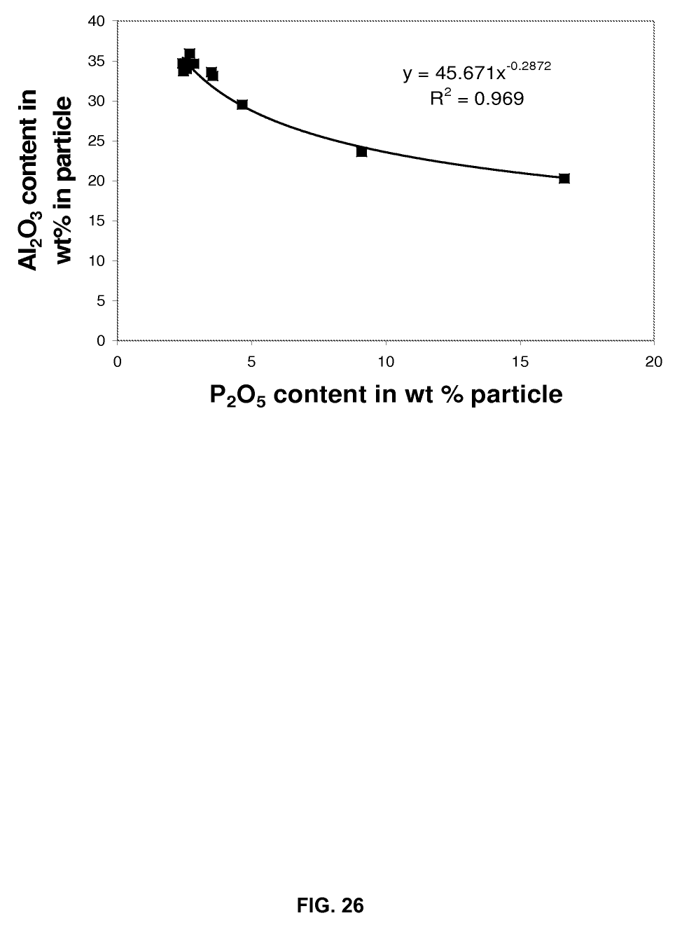

For Al₂O₃ concentrations in clay-sized kyanite-rich particle aggregates treated with a 1% H₃PO₄ solution for one hour, data from EDS analyses indicated that the correlation between Al₂O₃ and P₂O₅ tends to be very high with an R^{2=0.969}. FIG. 26 shows an X-Y plot of this EDS data. These data indicate that kyanite is a major control on sorption of phosphate.

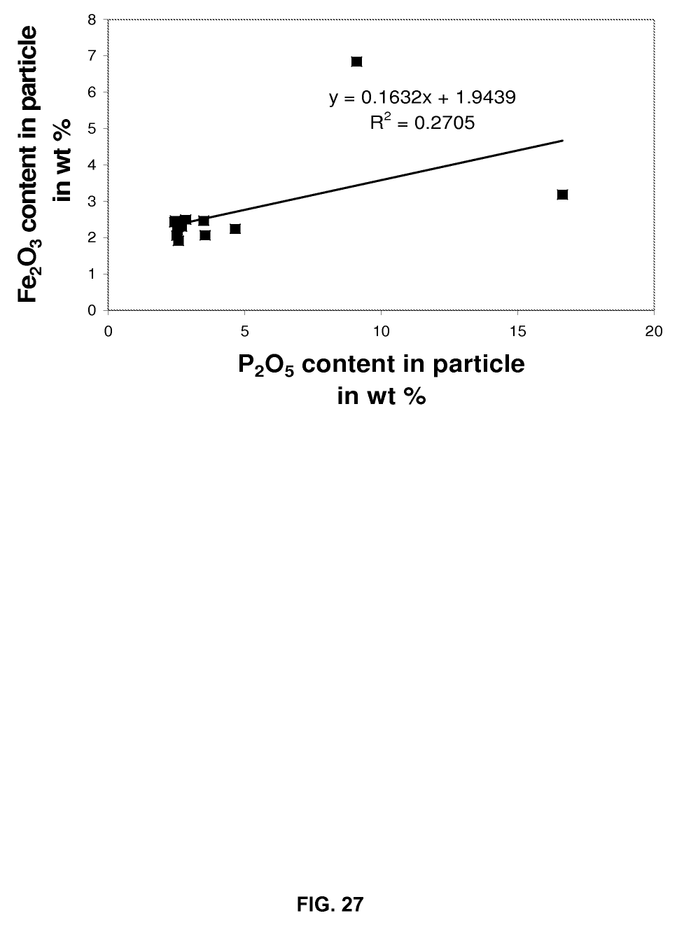

For Fe₂O₃ concentrations in clay-sized kyanite-rich particle aggregates treated with a 1% H₃PO₄ solution for one hour, data from EDS analyses indicated that the correlation between Fe₂O₃ and P₂O₅ tends to be present but weak with an R²=0.2705. FIG. 27 shows an X-Y plot of this EDS data. These data indicate Fe oxides play a role in phosphate sorption even when they are not abundant.

X-ray diffraction patterns on representative mixtures of the technology were obtained on a modified Siemens D-5000, equipped with a Peltier detector allowing low intensity peaks to be observed. Using PDF#00-011-0046, the most intense peak for kyanite is the (−211) at ˜3.18 Å. Using PDF# 00-046-1045, the most intense peak for quartz is the (101) at 3.34 Å. Using PDF# 00-033-0664, the most intense peak for hematite is (100) at 2.700 Å.

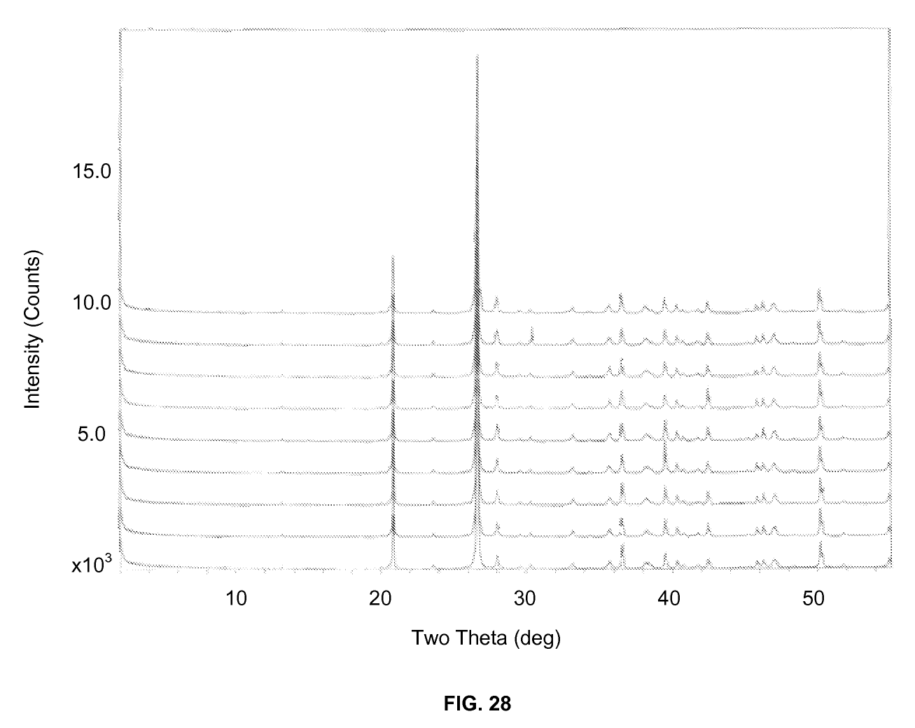

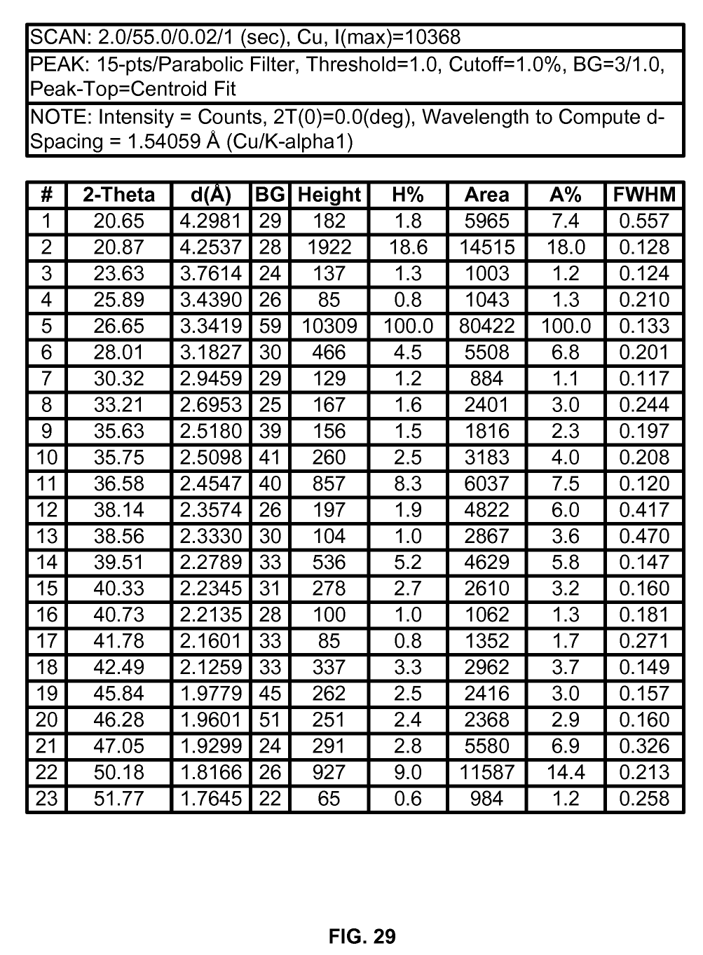

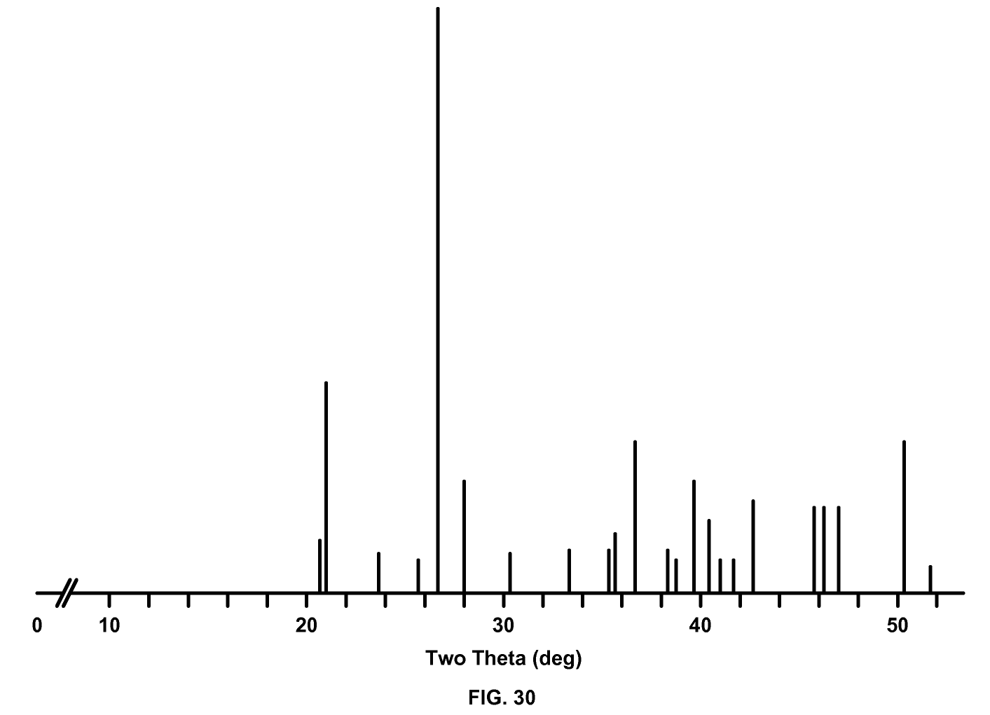

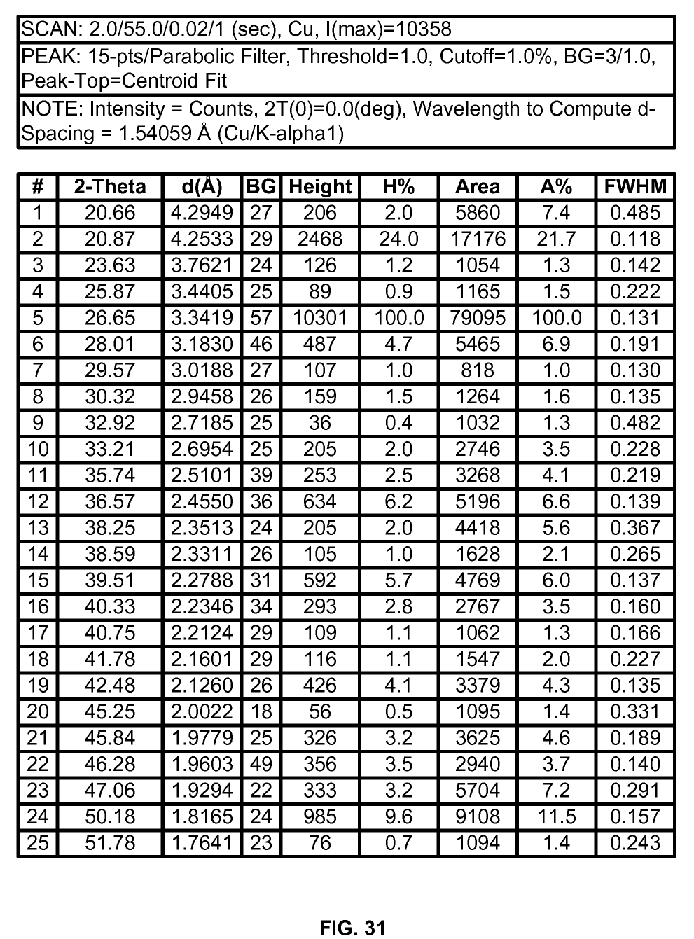

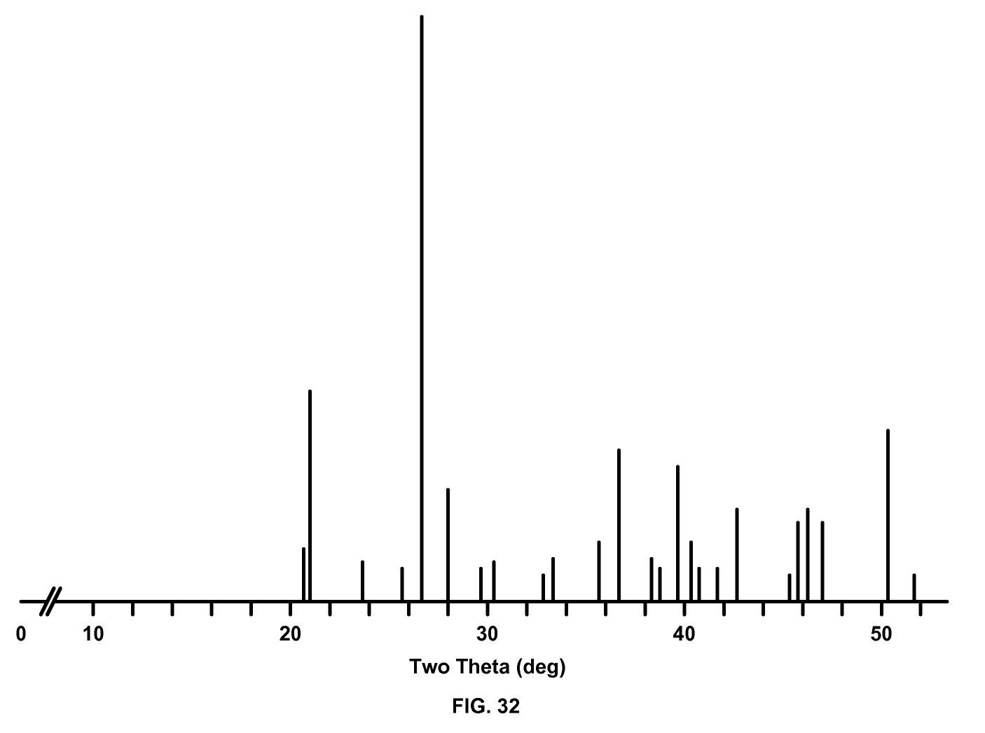

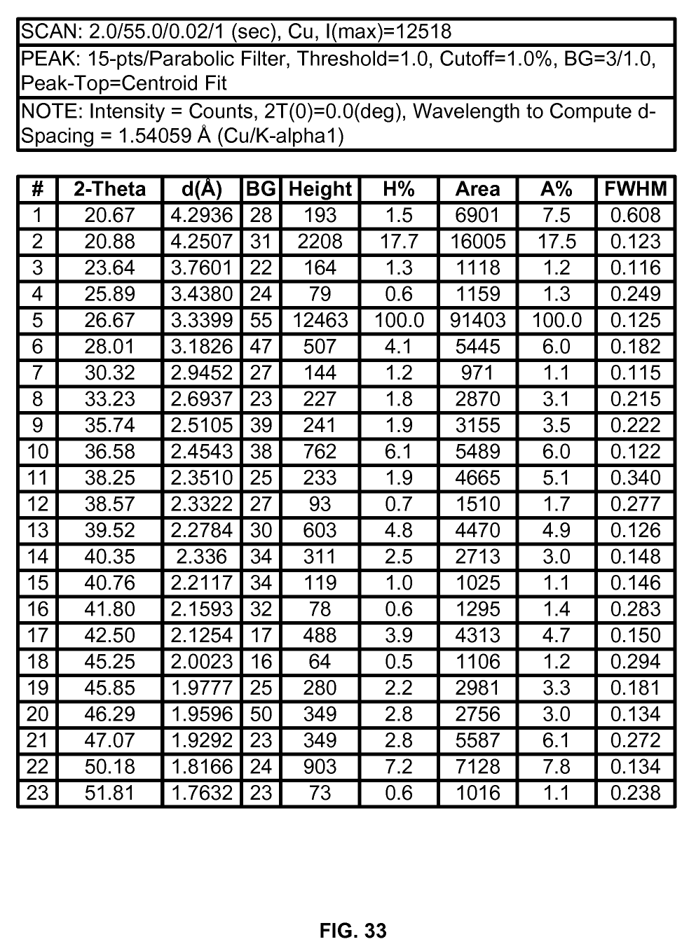

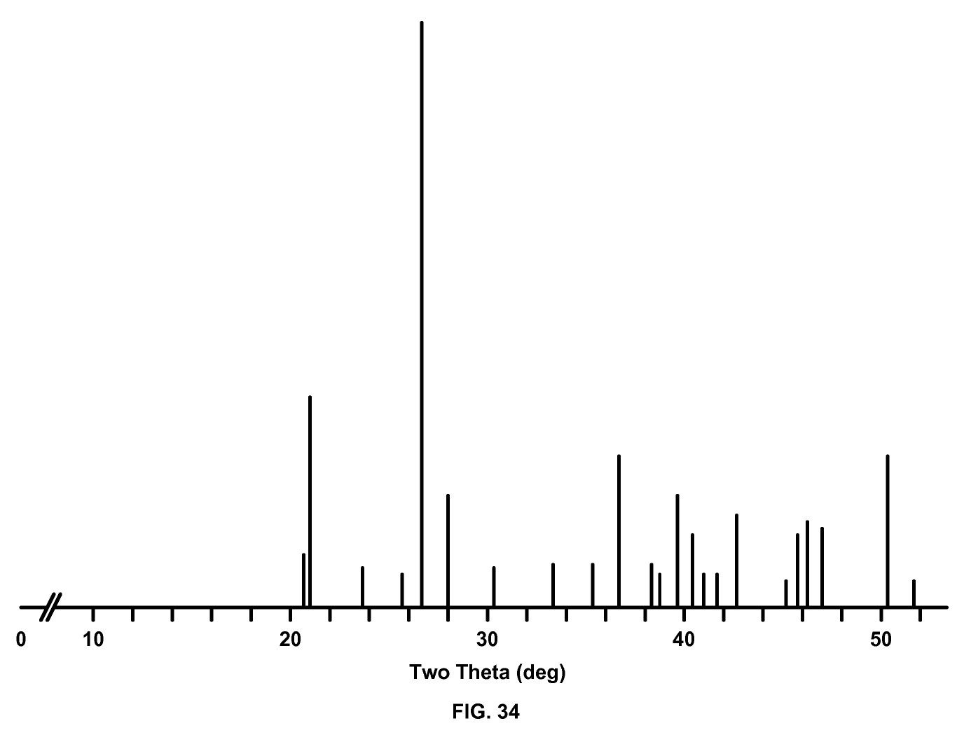

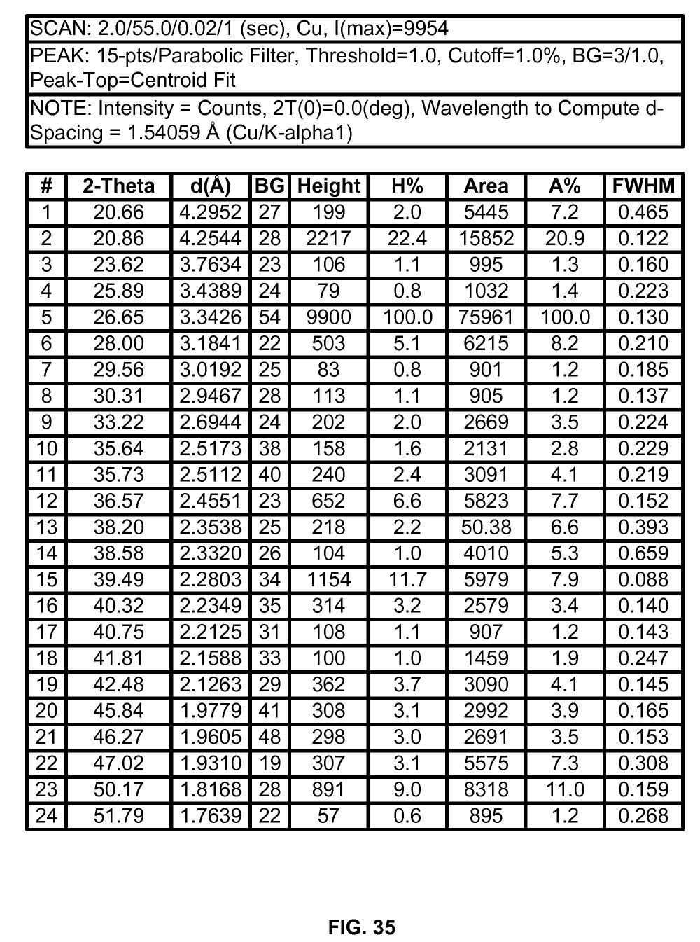

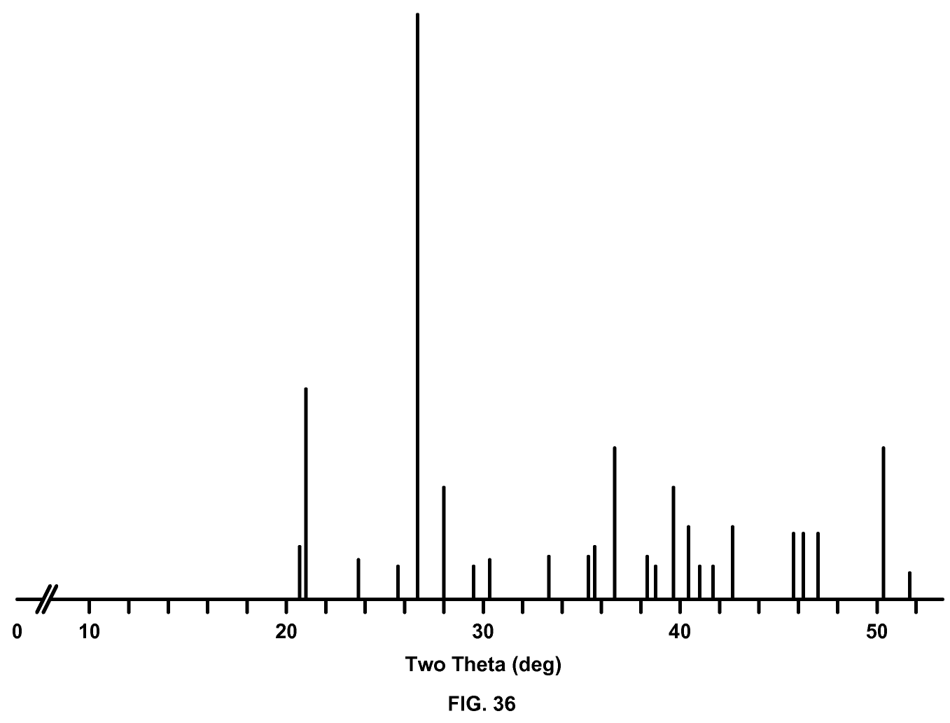

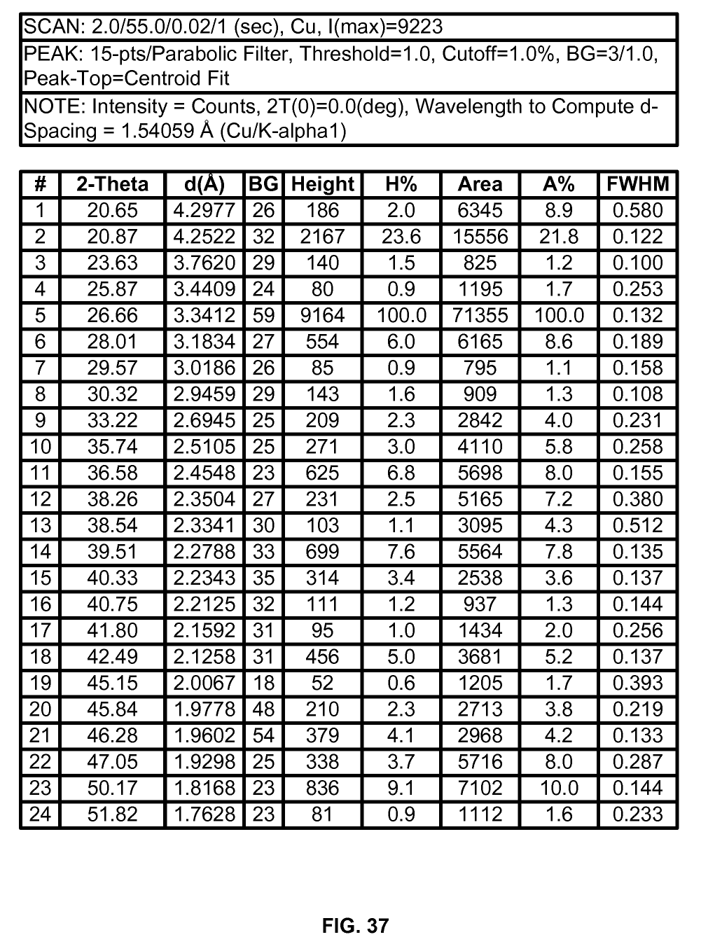

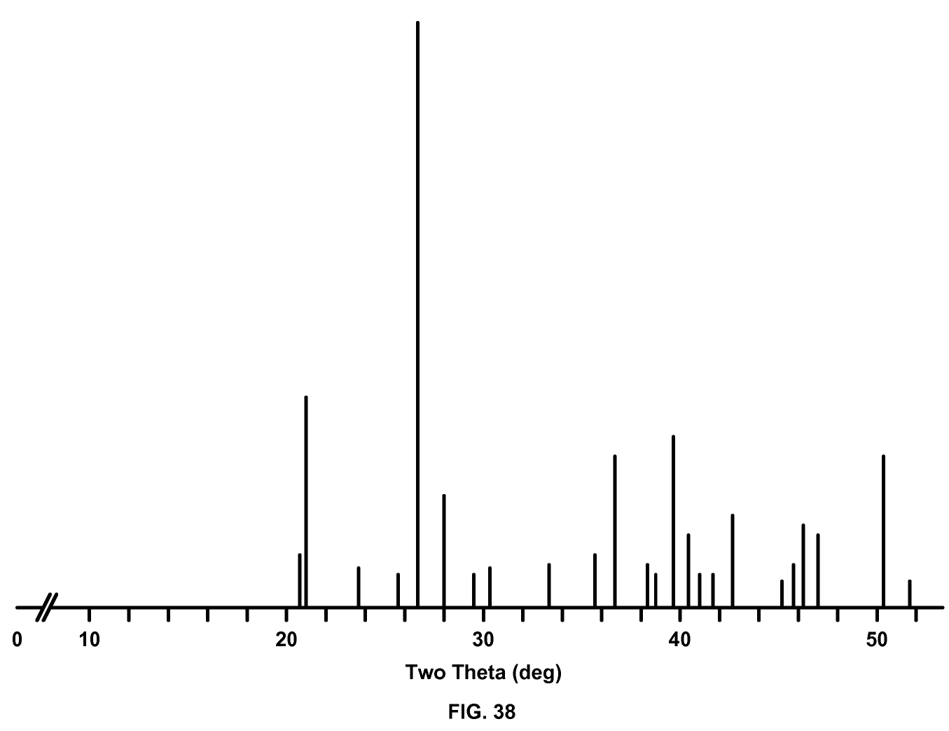

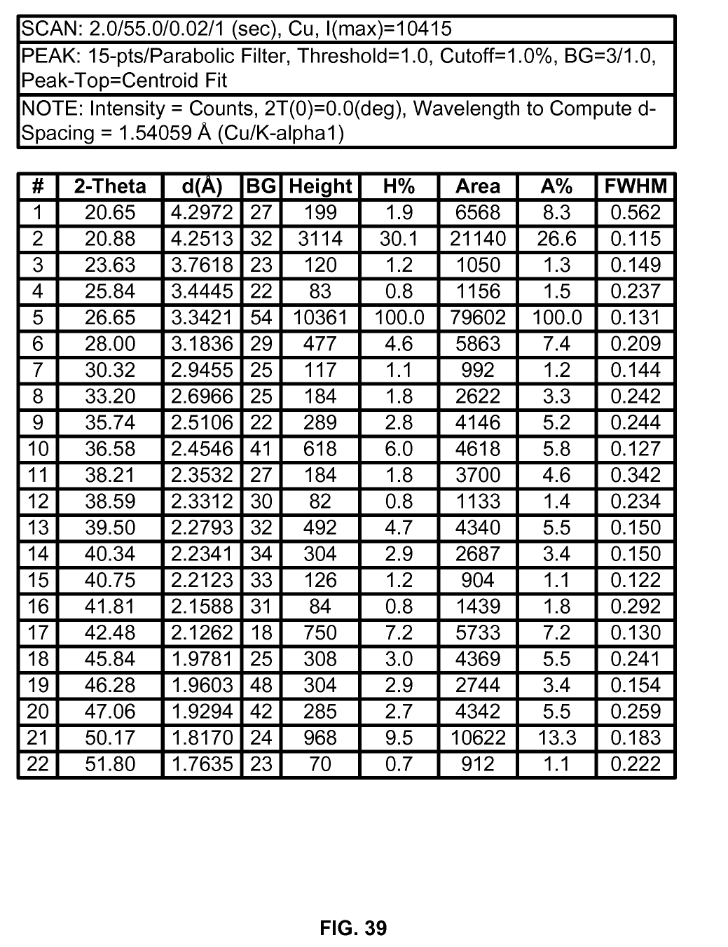

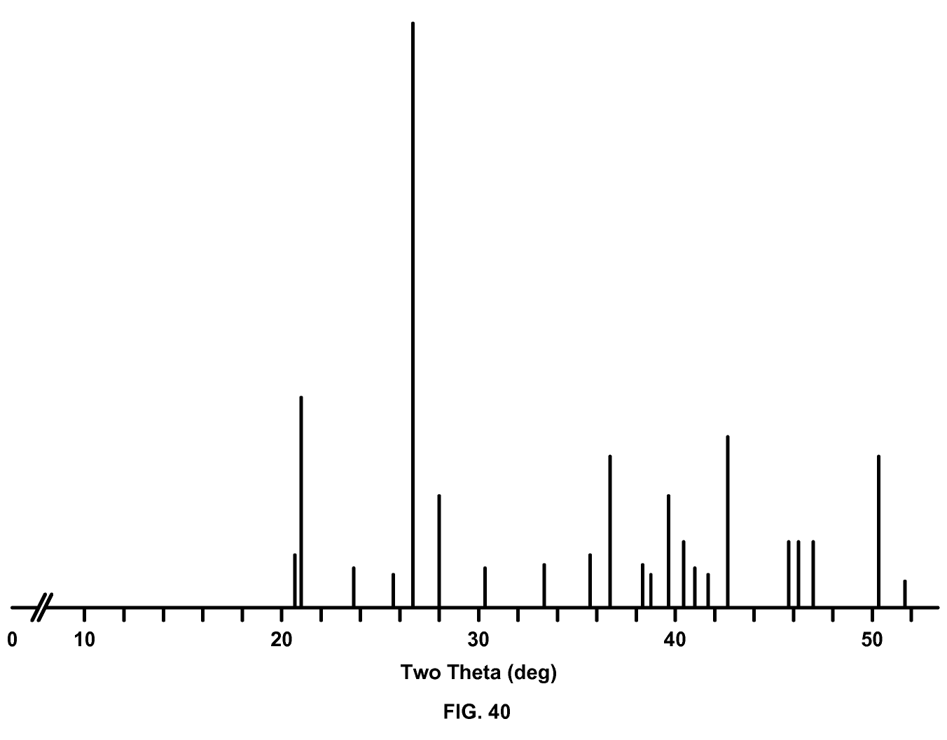

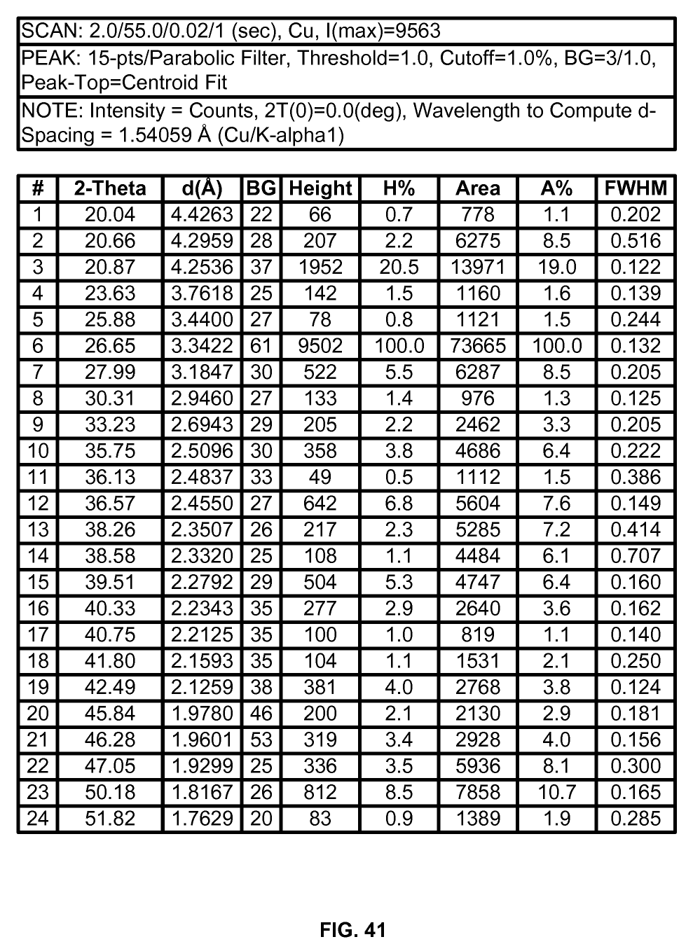

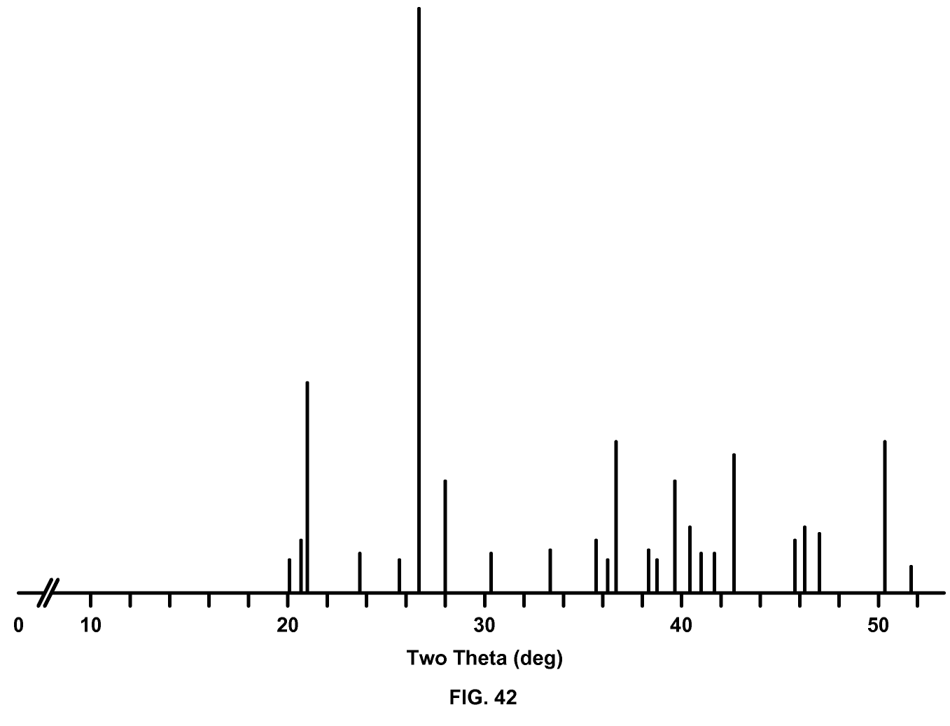

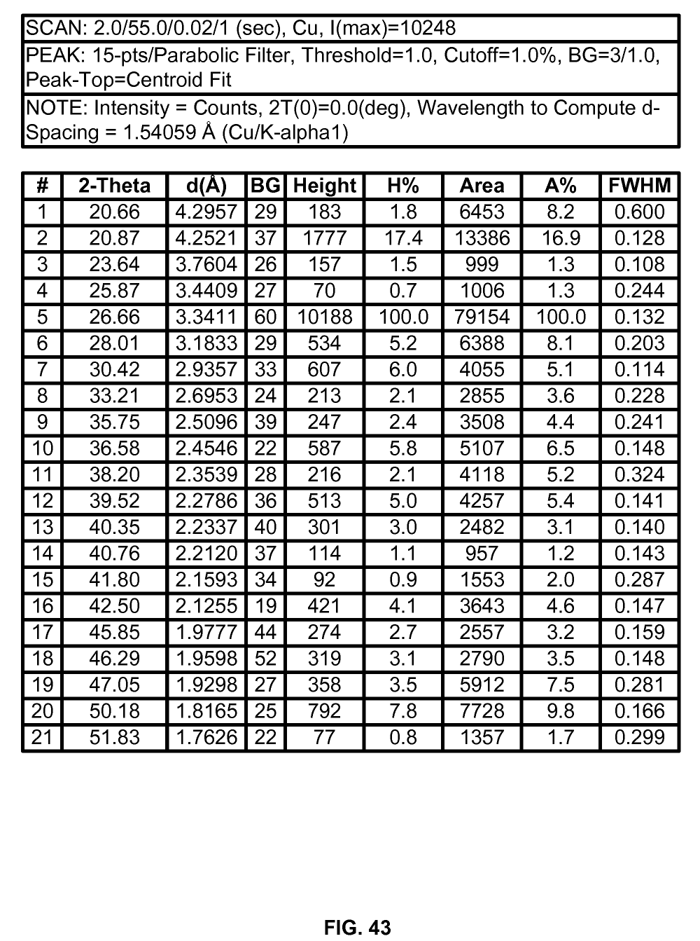

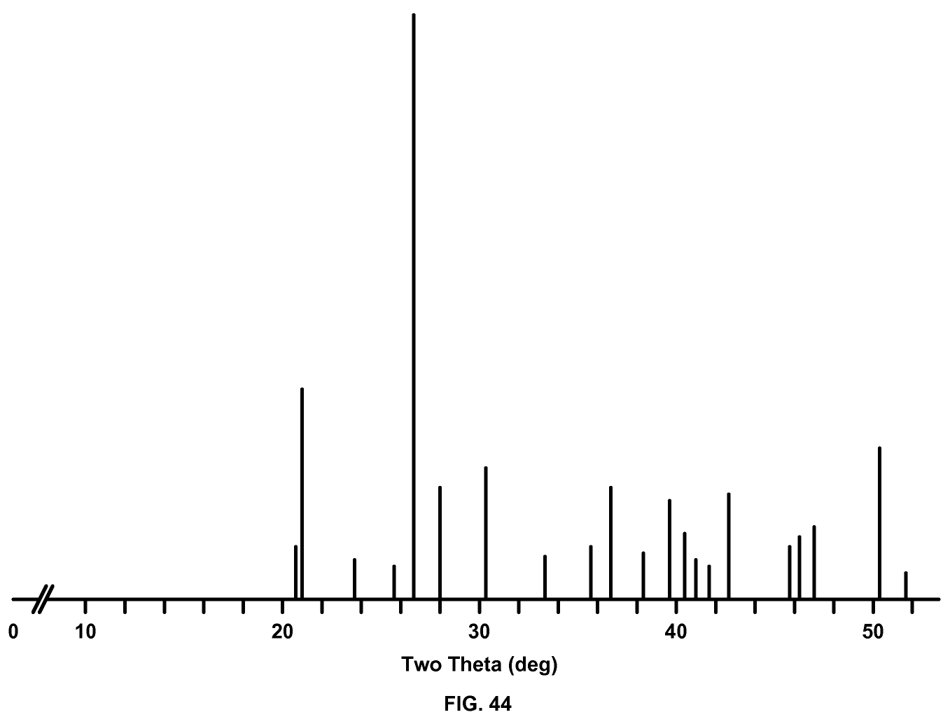

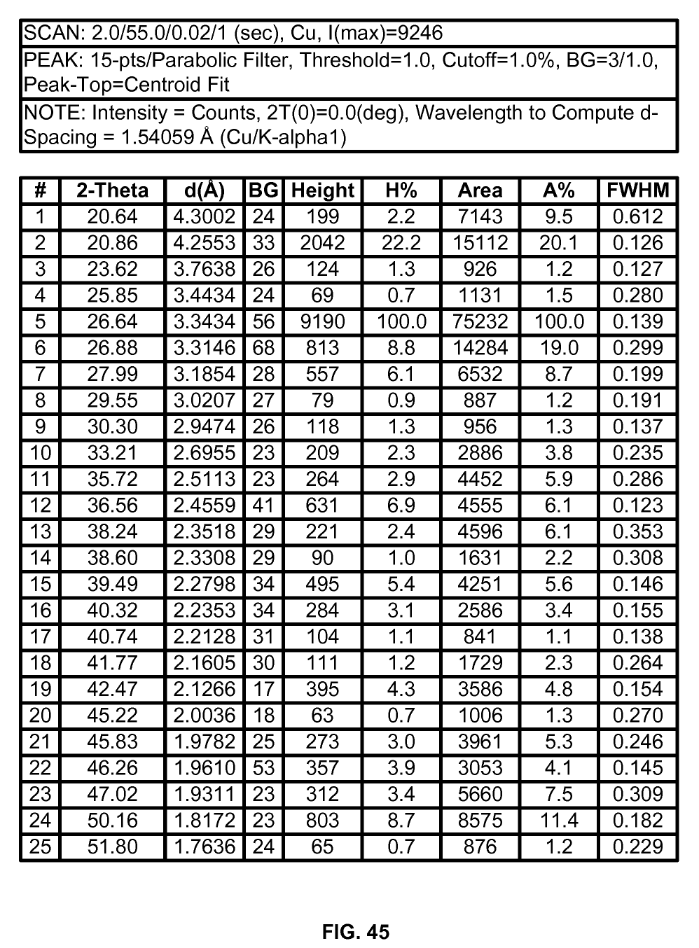

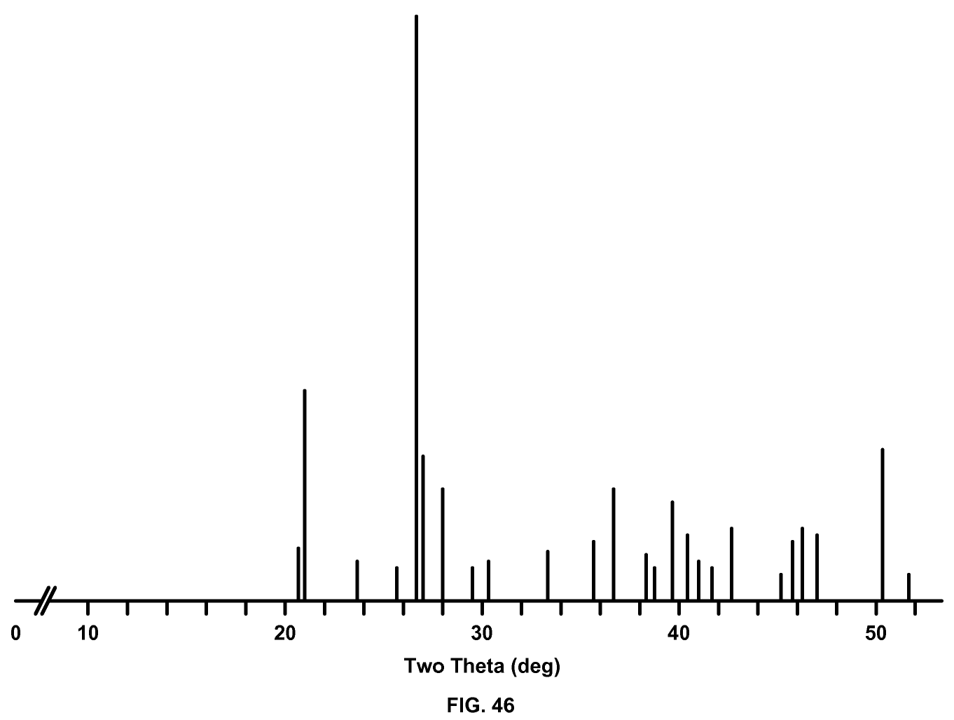

X-ray diffraction patterns may also be obtained from multiple representative mixtures of which had approximately 35% kyanite, 60% quartz, and 5% hematite as controlled mineral phases purposefully introduced in the mixture. Diffraction data and their corresponding X-ray diffraction patterns for experiments performed on various samples of synthetic soil are provided in FIGS. 28-46. Quartz strongly diffracts X-rays and in all cases the (101) peak was the most intense. Comparing the area of the kyanite (−211) peak and the quartz (101) using percentages for a representative mixture of the technology yields a range of about 6.0% to about 8.7% with an average of about 7.68%. The apparent disparity of area percentages compared to the known amounts in the mixtures may be explained by, for example, differences in X-ray scattering efficiencies of aluminum compared to silicon; the different crystal structures of kyanite and quartz; the higher degree of crystallinity of quartz compared to kyanite; and the difference in particle shape and crystal morphology of quartz and kyanite. The hematite (100) may overlap with two kyanite peaks at 2.69 Å. Thus, the comparatively small amounts of hematite in the mixture detected with powder X-ray diffraction may not be as accurate or feasible.

VII. Embodied Applications

The synthetic soil can be made in various locales, such as on site in concrete mixers, manufacturing plants, etc. Progress of the reaction(s) can be monitored by using simple color changes. As an application example, a synthetic soil system may be introduced into the ecosystem where the synthetic nanoparticle soil material may be distributed over an existing clay liner. Afterwards, topsoil and vegetation can be placed over the synthetic nanoparticle soil material. A water source can be introduced to these layers.

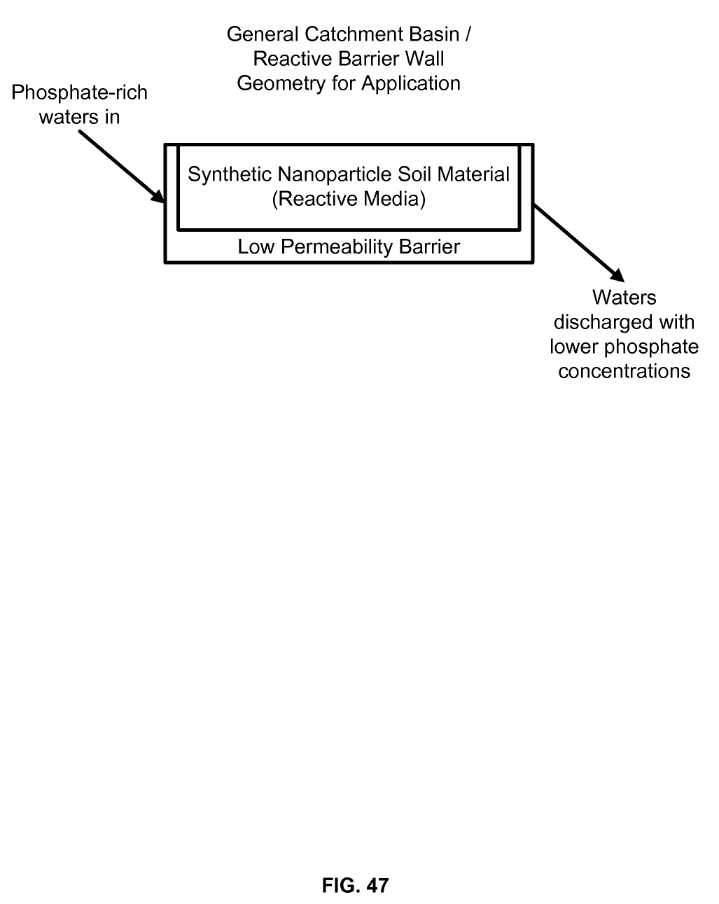

For example, the synthetic soil can be used in catchment basins or reactive barrier wall systems. Referring to FIG. 47, as phosphate-rich water flows into a general catchment basin or reactive barrier, the phosphate-rich water may mix with the synthetic soil, which may be placed on top of a low permeability barrier. Nonlimting examples of low permeability barriers include a clay liner, geotextile, concrete, metal, and plastic container. Serving as a filter, the synthetic soil may capture phosphate, which may result in waters being discharged with lower phosphate concentrations.

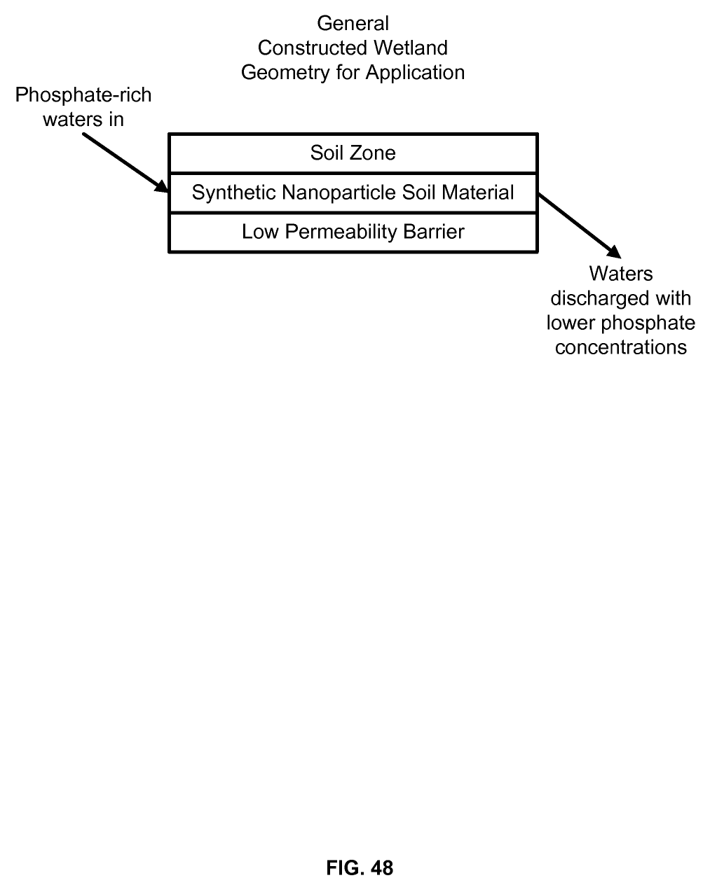

The synthetic soil may also be applied in wetlands, as shown in FIG. 48. In a constructed wetland, three layers may be present. The top layer may be a soil zone. The soil zone may comprise plants, nutrients, organic matter and inorganic components. The middle layer may be the reactive media (the synthetic soil). The bottom layer may be a low permeability barrier (e.g., a clay liner, geotextile, etc.). Similar to the catchment basin example, as phosphate-rich waters flow through these layers, the synthetic soil may absorb at least some of the phosphate. As a result, water that is discharged may have lower phosphate concentrations.

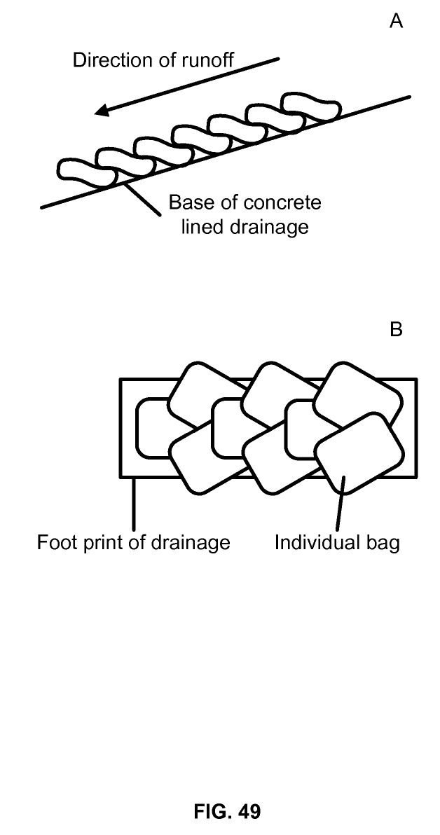

Alternatively, the synthetic soil may even be contained in a semi-permeable material and used to line existing drainage systems as shown in FIG. 49. The notion is that as water runoff pours through the drainage and contacts the semi-permeable material filled with the synthetic soil, the synthetic soil would absorb at least some of the phosphates in the water runoff.

The foregoing descriptions of the embodiments of the invention have been presented for purposes of illustration and description. They are not intended to be exhaustive or be limiting to the precise forms disclosed, and obviously many modifications and variations are possible in light of the above teaching. The illustrated embodiments were chosen and described in order to best explain the principles of the invention and its practical application to thereby enable others skilled in the art to best utilize it in various embodiments and with various modifications as are suited to the particular use contemplated without departing from the spirit and scope of the invention. In fact, after reading the above description, it will be apparent to one skilled in the relevant art(s) how to implement the invention in alternative embodiments. Thus, the invention should not be limited by any of the above described example embodiments. For example, the invention may be practiced over marshlands, areas with airport fuselage runoffs, water treatment plants, etc.

In addition, it should be understood that any figures, graphs, tables, examples, etc., which highlight the functionality and advantages of the invention, are presented for example purposes only. The architecture of the disclosed is sufficiently flexible and configurable, such that it may be utilized in ways other than that shown. For example, the steps listed in any flowchart may be reordered or only optionally used in some embodiments.

Further, the purpose of the Abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical invention of the application. The Abstract is not intended to be limiting as to the scope of the invention in any way.

Furthermore, it is the applicants' intent that only claims that include the express language “means for” or “step for” be interpreted under 35 U.S.C. § 112, paragraph 6. Claims that do not expressly include the phrase “means for” or “step for” are not to be interpreted under 35 U.S.C. § 112, paragraph 6.

A portion of the invention of this patent document contains material which is subject to copyright protection. The copyright owner has no objection to the facsimile reproduction by anyone of the patent document or the patent invention, as it appears in the Patent and Trademark Office patent file or records, but otherwise reserves all copyright rights whatsoever.

What is claimed is:

1. A synthetic nanoparticle soil material comprising about 0.5% to about 20% metal powder by mass, and about 0.5% to about 30% mineral powder by mass, mixed together with quartz-rich sand and a polymorph mineral of aluminum silicate, creating a sand mixture to which the sand mixture is mixed with a silicic acid solution.

2. A synthetic nanoparticle soil material according to claim 1, wherein the ratio of the quartz-rich sand to the polymorph mineral of aluminum silicate is 1:99 to 99:1.

3. A synthetic nanoparticle soil material according to claim 1, wherein the polymorph mineral of aluminum silicate is selected from a group consisting of:
a. kyanite;
b. andalusite;
c. sillimanite;
d. mullite; and
e. variants thereof.

4. A synthetic nanoparticle soil material according to claim 1, wherein the silicic acid solution is prepared with a ratio of silicic acid powder to water being 1:99 to 99:1.

5. A method for producing synthetic nanoparticle soil materials comprising:
a. creating a sand mixture by mixing a metal powder and a mineral powder with quartz-rich sand and a polymorph mineral of aluminum silicate, the metal powder constituting about 0.5% to about 20% of the synthetic nanoparticle soil materials by mass, and the mineral powder constituting about 0.5% to about 30% of the synthetic nanoparticle soil materials by mass; and
b. mixing the sand mixture with a silicic acid solution.

6. A method according to claim 5, wherein the ratio of the quartz-rich sand to the polymorph mineral of aluminum silicate is 1:99 to 99:1.

7. A method according to claim 5, wherein the polymorph mineral of aluminum silicate is selected from a group consisting of:
a. kyanite;
b. andalusite;
c. sillimanite;
d. mullite; and
e. variants thereof.

8. A method according to claim 5, wherein the silicic acid solution is prepared by mixing silicic acid powder with water, where the ratio of the silicic acid powder to the water is 1:99 to 99:1.

9. A method according to claim 5, further including creating a resulting mixture by evaporating the silicic acid solution that has been mixed with the sand mixture.

10. A method according to claim 9, further including agitating the resulting mixture.

11. A method according to claim 10, further including re-saturating the resulting mixture at least once.

12. A method according to claim 10, further including mechanically separating the metal powder from the resulting mixture.

13. A synthetic nanoparticle soil material production system comprising:
a. a sand mixer configured to create a sand mixture by mixing
i. a metal powder that constitutes about 0.5% to about 20% of a synthetic nanoparticle soil material by mass;
ii. a mineral powder that constitutes about 0.5% to about 30% of the synthetic nanoparticle soil material by mass;
iii. quartz-rich sand; and
iv. a polymorph mineral of aluminum silicate; and
b. a silicic acid mixer configured to mix the sand mixture with a silicic acid solution.

14. A system according to claim 13, further including a silicic acid solution preparer configured to create the silicic acid solution by mixing silicic acid powder with water, where the ratio of the silicic acid powder to the water is 1:99 to 99:1.

15. A system according to claim 13, further including a drying chamber configured to create a resulting mixture by evaporating the silicic acid solution that has been mixed with the sand mixture.

16. A system according to claim 15, further including an agitator configured to agitate the resulting mixture.

17. A system according to claim 15, further including a metal powder separator configured to mechanically separate the metal powder from the resulting mixture.

18. A system according to claim 17, further including a recycler configured to recycle the metal powder that is separated.

19. A system according to claim 13, wherein the ratio of the quartz-rich sand to the polymorph mineral of aluminum silicate is 1:99 to 99:1.

20. A system according to claim 13, wherein the polymorph mineral of aluminum silicate is selected from a group consisting of:
a. kyanite;
b. andalusite;
c. sillimanite;
d. mullite; and
e. variants thereof.
